(19) United States
(12) Patent Application Publication
(10) Pub. No.: US 2025/0218946 A1
(43) Pub. Date: Jul. 3, 2025

(54) ASYMMETRIC SOURCE/DRAIN SPACER WITH SHIFTED VBPR AND BSPDN

(71) Applicant: International Business Machines Corporation, Armonk, NY (US)

(72) Inventors: Gideon Oyibo, Rensselaer, NY (US); Tao Li, Slingerlands, NY (US); Ruilong Xie, Niskayuna, NY (US); Nicolas Jean Loubet, Guilderland, NY (US)

(21) Appl. No.: 18/398,419

(22) Filed: Dec. 28, 2023

(51) Int. Cl. H01L 23/528; H01L 21/8238; H01L 27/092; H01L 29/06; H01L 29/417; H01L 29/423; H01L 29/66; H01L 29/775

(52) U.S. Cl. CPC H01L 23/5286; H10D 30/014; H10D 30/43; H10D 30/6729; H10D 30/6735; H10D 62/121; H10D 84/0186; H10D 84/038; H10D 84/85

(57) ABSTRACT

A semiconductor structure including first and second FET devices and a method of forming the structure. A first FET is formed with a first source/drain structure and a second FET is formed with a second source/drain structure. A via backside power rail (VBPR) metal contact structure is formed between the first FET device and the second FET device, the VBPR contact structure having a first portion contacting an underlying backside power rail and a second via portion electrically contacting only a sidewall of the first source/drain of the first FET device. The first portion of the VBPR contact structure contacting the backside power rail is of a first width and the second via portion of the VBPR contact structure contacting only a sidewall of the source or drain of the first FET device is of a second width, the first width greater than the second width.

### BACKGROUND

The present disclosure relates to a semiconductor structure and a method of forming the same. More particularly, the present disclosure relates to integrated circuit (IC) chips, in particular to the delivery of power to the active devices on the chip.

As semiconductor processing for the fabrication of IC chips continues to evolve towards increasing device-density, this has put a strain on the design and fabrication of the interconnects between the various components including the delivery of power from buried power delivery network to devices at front end of line (FEOL) of the IC, consisting mainly of the active devices.

In some cases, a power delivery network or PDN is specifically formed by conductors and vias connected to Vdd/Vss terminals of the chip, e.g., for delivering power to the individual devices, e.g., built in the front end. The integration of the power delivery network in the back end of line has become particularly challenging because of the increase in the device density.

Known solutions to this problem consists in the production of the majority of layers of the power delivery network on the back side of the wafer instead of on the front side. These layers are thus not formed on top of the front end of line, but on the opposite side of the wafer, i.e., on the backside of the semiconductor substrate onto which the active devices have been built.

Structures such as a via backside power rail (VBPR) structure are provided which enable connection from the power delivery network or PDN to terminals of the active devices, e.g., field effect transistors (FETs) formed during FEOL processing on the chip, for delivering power to the individual devices in the front end.

### SUMMARY

In one aspect there is provided semiconductor device structures and a method for forming a semiconductor device.

In an aspect, the semiconductor device structures include adjacent first gate-all-around (GAA) semiconductor transistor device comprising adjacent GAA FET devices, each GAA FET device having a vertical stack of spaced apart nanosheet (NS) channels surrounded by a gate structure. The structures further include a shifted VBPR structure in contact with a source or drain (S/D) sidewall of one of the adjacent GAA FET devices.

In this aspect, the shifted VBPR structure includes a dielectric via thereby preventing electrical contact of the BPR to the second adjacent GAA FET device.

Further, the shifted VBPR structure has a first bottom critical dimension (CD1) between a bottom of the two adjacent GAA FET devices and a buried interlevel dielectric (BILD) region and a second critical dimension (CD2) that is between the dielectric via and S/D sidewall of a first GAA FET device. The first bottom critical dimension (CD1) provides a sufficient metal volume for robust power delivery performance.

In an embodiment, the adjacent first and second GAA FET devices have an asymmetric S/D sidewall spacer that is on an opposite side of the S/D sidewall and/or the BILD sidewall that is in contact with the shifted VBPR which takes up less space allowing more shrinking for more advanced technological nodes.

In an aspect, the shifted VBPR structure further connects with a first middle-of-line (MOL) contact. The second adjacent GAA FET device with MOL contact is separated from first MOL contact and shifted VBPR structure by the dielectric via.

In one aspect, there is provided a semiconductor structure. The semiconductor structure comprises: a first dielectric material layer having a backside power rail structure; a second dielectric material layer atop the first dielectric material layer and having a first field effect transistor (FET) device and a second FET device; and a backside metal contact structure within the second dielectric layer between the first FET device and the second FET device, the backside metal contact structure having a first portion contacting the backside power rail structure and a second via portion electrically contacting only a sidewall of a source or drain structure of the first FET device.

In a further aspect, there is provided a method of forming a semiconductor structure. The method comprises: forming atop a substrate layer of a first wafer, an interlevel dielectric (ILD) material layer; forming at the ILD material layer a first field effect transistor (FET) device, and a second FET device; forming a trench opening between a sidewall of a source or drain structure of the first FET device and a facing sidewall of a source or drain structure of the second FET device, the trench opening exposing a sidewall of the source or drain structure of the first FET device and exposing a facing sidewall of the source or drain structure of the second FET device; filling the trench opening with a metal contact material to form a backside metal contact structure contacting the exposed sidewalls of the source or drain structures of the first FET device and second FET device; removing a portion of the backside metal contact structure contacting the sidewall of the source or drain structure of the first FET device; and filling the removed portion with a dielectric material such that a shifted portion of the backside metal contact structure remains in electrical contact with only the facing sidewall of the source or drain structure of the second FET device.

Yet in another aspect, there is provided a semiconductor structure. The semiconductor structure comprises: a first dielectric material layer having a first backside power rail structure and a second backside power rail structure; a second dielectric material layer atop the first dielectric material layer and having a first field effect transistor (FET) device and a second FET device, the first FET device and second FET device of a first conductivity type, the second dielectric material layer having a third FET device and a fourth FET device of a second conductivity type; and a first backside metal contact structure within the second dielectric layer between the first FET device and the second FET device, the backside metal contact structure having a first portion contacting the first backside power rail structure and a second via portion electrically contacting only a sidewall of a source or drain structure of the first FET device; and a second backside metal contact structure within the second dielectric layer between the third FET device and the fourth FET device, the second backside metal contact structure having portions contacting the second backside power rail structure and portions wholly contacting sidewalls of both a source or drain structure of each third FET device and fourth FET device.

Further features as well as the structure and operation of various embodiments are described in detail below with reference to the accompanying drawings. In the drawings, like reference numbers indicate identical or functionally similar elements.

### BRIEF DESCRIPTION OF THE DRAWINGS

FIG. 1 shows a top down view of formed vertically stacked gate-all-around (GAA) nanosheet (NS) field effect transistor device structures formed in accordance with an embodiment;

FIG. 1A shows a cross-sectional view of the semiconductor device structures taken along line Y-Y of FIG. 1; and FIG. 1B shows a cross-sectional view of the semiconductor device structures taken along line X-X of FIG. 1;

FIG. 2 depicts a top down view indicating a layout on a wafer substrate of locations on which semiconductor structures such as stacked GAA NS FET structures including asymmetric source/drain spacers and shifted VBPR structures are formed according to embodiments of the present disclosure;

FIG. 2A depicts a cross-sectional view of an intermediate structure taken along line Y1-Y1 of a top-down layout view of FIG. 2 and FIG. 2B depicts a cross-sectional view of the intermediate structure taken along line X-X depicted in FIG. 2;

FIG. 2C-1 depicts a resulting intermediate semiconductor structure taken along line Y1-Y1 of FIG. 2 after layer patterning and deposition steps to form dummy gate structures; and FIG. 2C-2 depicts the resulting intermediate semiconductor structure taken along line X1-X1 of FIG. 2;

FIG. 2D-1 depicts a resulting intermediate semiconductor structure taken along line Y1-Y1 of FIG. 2 after further etching steps to selectively remove a sacrificial SiGe55% layer underlying each individual stacked nanosheet structures for GAA FET devices to be formed; and FIG. 2D-2 depicts the resulting intermediate semiconductor structure taken along line X1-X1 of FIG. 2;

FIG. 2E-1 depicts a resulting intermediate semiconductor structure taken along line Y1-Y1 of FIG. 2 after further processing steps to recess edges of each individual stacked nanosheet structures for GAA FET devices to be formed including the forming of inner dielectric spacers and the epitaxial growing of both source and drains for each GAA FET devices to be formed; and FIG. 2E-2 depicts the resulting intermediate semiconductor structure taken along line X1-X1 of FIG. 2;

FIG. 2F-1 depicts a resulting intermediate semiconductor structure taken along line Y1-Y1 of FIG. 2 after further processing steps to trim the epitaxial grown source and drain structures to remove the top overlapping S/D epi edge structures and reveal the top edges of the S/D sidewall spacers at each GAA FET gate structure to be formed; and FIG. 2F-2 depicts the resulting intermediate semiconductor structure taken along line X1-X1 of FIG. 2;

FIG. 2G-1 depicts a resulting intermediate semiconductor structure taken along line Y1-Y1 of FIG. 2 after further processing steps to pattern and deposit a top organic planarization layer (OPL) of a dielectric material on top of the structures depicted in FIGS. 2F-1 and 2F-2; and FIG. 2G-2 shows the resulting intermediate semiconductor structure taken along line X1-X1 of FIG. 2;

FIG. 2H-1 depicts a resulting intermediate semiconductor structure taken along line Y1-Y1 of FIG. 2 after further processing steps to pattern and etch the portions of gate dielectric spacers that are exposed above the top surface of the organic planarization layer such that gate dielectric sidewall spacers are recessed to expose the dummy gate dielectric hardmask portion according to an embodiment; and FIG. 2H-2 shows the resulting intermediate semiconductor structure taken along line X1-X1 of FIG. 2;

FIG. 2I-1 depicts a resulting intermediate semiconductor structure taken along line Y1-Y1 of FIG. 2 after further processing steps to lithographically pattern and deposit a protective dielectric material sidewall spacer atop the surfaces of the gate sidewall dielectric spacers surrounding dummy gates; and FIG. 2I-2 shows the resulting intermediate semiconductor structure taken along line X1-X1 of FIG. 2;

FIG. 2J depicts the top layout view of the resulting intermediate semiconductor structures shown in FIG. 2 further indicating locations of openings for exposing S/D sidewall spacers to be pulled down;

FIG. 2J-1 depicts a resulting intermediate semiconductor structure taken along line Y1-Y1 of FIG. 2J after processing steps to deposit, lithographically pattern and etch a dielectric material layer leaving portions to protect or “keep” certain S/D sidewall spacers of desired GAA NS FET devices to be formed; and FIG. 2J-2 shows the resulting intermediate semiconductor structure taken along line X1-X1 of FIG. 2;

FIG. 2K-1 depicts a resulting intermediate semiconductor structure taken along line Y1-Y1 of FIG. 2J after exposed S/D spacer pull down processing steps to etch and remove exposed opposing S/D dielectric sidewall spacer portions within opening of adjacent S/D structures of respective adjacent PFET devices to be formed and further etch to remove exposed opposing S/D dielectric sidewall spacer portions within an opening of adjacent S/D structures of adjacent NFET devices to be formed; and FIG. 2K-2 shows the resulting intermediate semiconductor structure taken along line X1-X1 of FIG. 2J;

FIG. 2L-1 illustrates a resulting intermediate semiconductor structure taken along line Y1-Y1 of FIG. 2 after removing the OPL in the structures shown in FIG. 2KI-1, 2K-2 and depositing an interlevel dielectric (ILD) material layer; and FIG. 2L-2 shows the resulting intermediate semiconductor structure taken along line X1-X1 of FIG. 2J;

FIG. 2M depicts the top layout view of the resulting intermediate semiconductor structures shown in FIG. 2 further indicating locations of formed trench openings for VBPR patterning after performing an ILD etch to open areas VBPR material deposition according to embodiments of the present disclosure;

FIG. 2M-1 depicts a resulting intermediate semiconductor structure taken along line Y1-Y1 of FIG. 2M after VBPR pattern processing steps to lithographically pattern and etch VBPR trench openings between adjacent FET devices being formed; and FIG. 2M-2 shows the resulting intermediate semiconductor structure taken along line X1-X1 of FIG. 2M;

FIG. 2N depicts the top layout view of the resulting intermediate semiconductor structures shown in FIG. 2 further indicating locations of VBPR structures resulting from VBPR patterning and VBPR metal material deposition according to embodiments of the present disclosure;

FIG. 2N-1 depicts a resulting intermediate semiconductor structure taken along line Y1-Y1 of FIG. 2N after VBPR pattern processing steps to lithographically pattern a mask and deposit VBPR metal and to fill holes of the structure of FIG. 2M-1; and FIG. 2N-2 shows the resulting intermediate semiconductor structure taken along line X1-X1 of FIG. 2N;

FIG. 2O depicts the top layout view of the semiconductor structures shown in FIG. 2N including further VBPR metal structures resulting from patterning and depositing VBPR metal material and CMP surface planarizing according to embodiments of the present disclosure;

FIG. 2O-1 depicts a resulting intermediate semiconductor structure taken along line Y1-Y1 of FIG. 2O after VBPR pattern and deposition processing steps including Middle-of-Line (MOL) processing to increase and extend VBPR metal coverage of GAA NS FET devices being formed; and FIG. 2O-2 shows the resulting intermediate semiconductor structure taken along line X1-X1 of FIG. 2O;

FIG. 2P depicts the top layout view of the resulting intermediate semiconductor structures shown in FIG. 2O further indicating resulting VBPR structures resulting from VBPR cut patterning and dielectric material fill steps for forming a dielectric via that results in a “shifted” VBPR metal material structure according to embodiments of the present disclosure;

FIG. 2P-1 depicts a resulting intermediate semiconductor structure taken along line Y1-Y1 of FIG. 2P after MOL level mask patterning and RIE etching to remove a contiguous portion of the VBPR metal structure that electrically connects to one side of the epitaxially grown S/D structure, remove contiguous portion of the overlying VBPR metal structure, and then fill the removed contiguous portion with ILD dielectric material according to an embodiment; and FIG. 2P-2 shows the resulting intermediate semiconductor structure taken along line X1-X1 of FIG. 2O;

FIG. 2Q-1 depicts a resulting intermediate semiconductor structure taken along line Y1-Y1 of FIG. 2P after forming BEOL structures atop the structures of FIG. 2P-1 and performing a carrier bonding step to bond a second carrier wafer to structures of the top BEOL level layer using known processes; and FIG. 2Q-2 shows the resulting intermediate semiconductor structure taken along line X1-X1 of FIG. 2P;

FIG. 2R-1 depicts a resulting intermediate semiconductor structure taken along line Y1-Y1 of FIG. 2P after performing steps to “flip” the wafer upon which structures are built and remove the substrate by performing a dry RIE etch selective to the etch stop layer; and FIG. 2R-2 shows the resulting intermediate semiconductor structure taken along line X1-X1 of FIG. 2P;

FIG. 2S-1 depicts a resulting intermediate semiconductor structure taken along line Y1-Y1 of FIG. 2P after further performing further processing steps upon the flipped wafer to remove the etch step layer and then removing the remaining substrate portion and that opens trenches that are filled with insulative BILD material to isolate the bottom VBPR structure of the shifted VBPR and isolate the VBPR structure between successive STI regions; and FIG. 2S-2 shows the resulting intermediate semiconductor structure taken along line X1-X1 of FIG. 2P;

FIG. 2T depicts the top layout view of the resulting intermediate semiconductor structures shown in FIG. 2P further indicating underlying bottom power rail conductor for providing a Vdd power to VBPR structure and underlying bottom power rail (BPR) conductor for providing a Vss power to VBPR structure according to embodiments herein; and

FIG. 2T-1 depicts a resulting intermediate semiconductor structure taken along line Y1-Y1 of FIG. 2T after further building, on the “flipped” wafer, a further BILD material layer atop the planar surface, and the forming of power rail conductors for providing a power to VBPR structures; and FIG. 2T-2 shows the resulting intermediate semiconductor structure taken along line X1-X1 of FIG. 2T.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

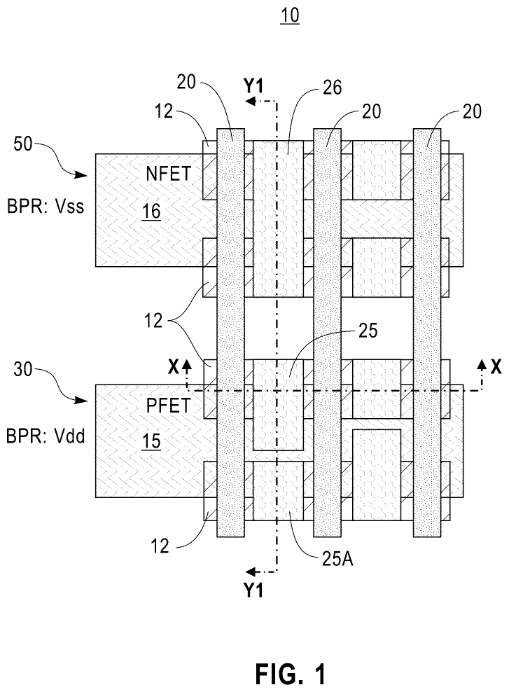

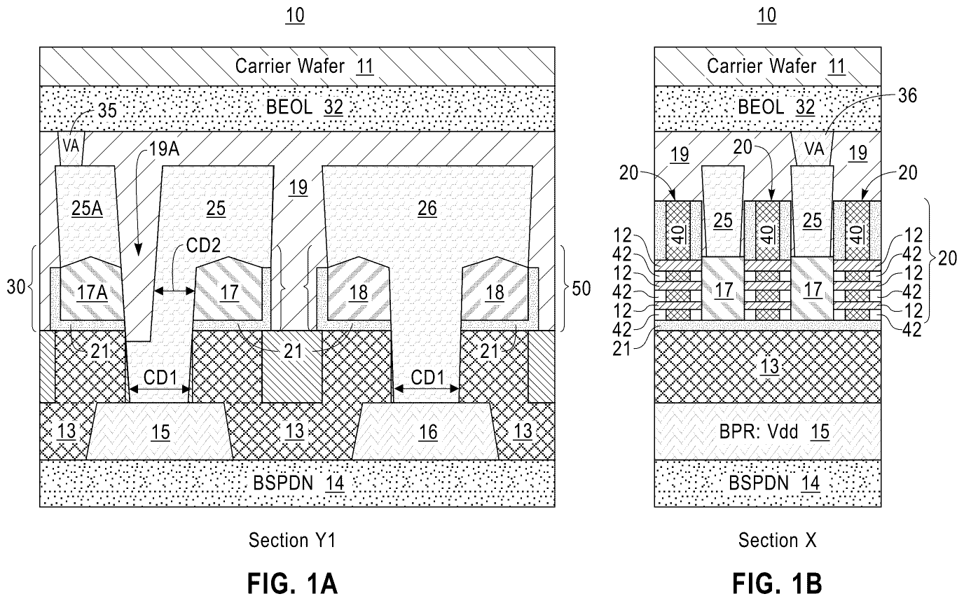

FIGS. 1, 1A, 1B show semiconductor device structures 10 according to aspects of the present disclosure. The semiconductor device structures 10 are formed on a carrier wafer 11 which include one or more first conductivity type FET transistor devices 30, e.g., p-type FET or “PFET devices” 30 (e.g., a vertically stacked P-type gate-all-around (GAA) nanosheet (NS) field effect transistor or PFET/PFETs or FinFETs) and one or more second conductivity type FET transistor devices 50, e.g., n-type FET or “NFET devices” 50 (e.g., a vertically stacked N-type gate-all-around (GAA) nanosheet field effect transistor or NFET/NFETs or FinFETs). Each of the NS FET devices, e.g., PFET devices 30, NFET devices 50, includes an epitaxial grown nanosheet stack including at least one formed Si NS channel layer 12. Further, each PFET or NFET has a source or drain (S/D) region including respective S/D structures including S/D sidewall structures that are epitaxially grown from and connecting opposing edges to the Si NS channel layers 12. Further, one or more S/D sidewall structures of a PFET device 30 is shown connected to a via backside power rail (VBPR) middle-of-line (MOL) contact structure 25 (“VBPR contact structure” 25) connecting to an underlying backside power rail (BPR) 15. The VBPR contact structure 25 includes a first portion of a first critical dimension width (CD1) connecting to the underlying BPR 15 and a shifted VBPR portion (e.g., a VBPR “shifted” to one side) contacting a Source or Drain (S/D) structure 17 of a second critical dimension width (CD2) wherein the first CD1>CD2. At least one other PFET device 30 includes a S/D structure 17A having a top surface connecting to a VBPR contact portion 25A that avoids a connection to the underlying BPR 15 according to embodiments of the disclosure.

In particular, FIG. 1 is a top layout view of the semiconductor device structures 10 that include an underlying backside power rail (BPR) 15 connected to a power source (e.g. Vdd) for carrying a first power supply voltage used for powering circuits and devices, and an underlying BPR 16 connected to a second power source (e.g. Vss) for carrying a second power supply voltage, e.g., a ground or common level voltage. As shown in FIGS. 1 and 1A depicting a cross-sectional view of the semiconductor structures 10 taken along the line Y-Y, each underlying BPR 15 and underlying BPR 16 is formed in a buried interlevel dielectric material layer 13 and includes bottom surfaces connecting to an underlying backside power delivery network (BSPDN) 14. The semiconductor device structures 10 include a low-k dielectric layer 19 formed above buried interlevel dielectric material layer 13 and including a portion isolating the PFET devices 30 and NFET devices 50. Further separating the PFET devices 30 and NFET devices 50 is a shallow trench isolation (STI) structure 140 that is formed below the low-k dielectric layer 19 underneath the portion isolating the PFET devices 30 and NFET devices 50. Within low-k dielectric layer 19 is a formed VBPR contact structure 25 connecting the underlying BPR 15 to an epitaxial grown source or drain (S/D) structure 17 of a PFET device 30. As shown in FIG. 1A, in accordance with an embodiment, further formed within low-k dielectric layer 19 is an isolated VBPR contact portion 25A that does not connect to the underlying BPR 15 however does connect with only the S/D structure 17A of another PFET device 30. This VBPR contact portion 25A is isolated from VBPR contact structure 25 by the presence of a buried dielectric via portion 19A that is formed as part of the low-k dielectric layer 19 and disposed between the formed S/D structures 17, 17A such that the buried dielectric via portion 19A only contacts the whole S/D structure 17A of the PFET device 30 and extends below the S/D structure 17A. Buried dielectric via portion 19A prevents VBPR contact structure 25 from contacting the S/D structure 17A of the PFET device 30. As further shown in FIG. 1A, the epitaxial grown S/D structures 17, 17A each include “asymmetric” S/D sidewall and bottom spacers 21 which are dielectric spacer structures having one sidewall portion removed at opposing sides of the S/D structures 17, 17A facing each other. Asymmetric S/D and bottom spacers 21 allow space for deposition of the interlevel dielectric via portion 19A and the VBBP contact structure 25 having a shifted VBPR portion of thinner width dimension CD2 connecting to sidewall of S/D structure 17. FIG. 1A shows the formed VBPR contact structure 25 connecting to the underlying BPR 15 having the first critical dimension width (CD1) between bottom of two adjacent PFETs in buried interlevel dielectric region 13 and the formed VBPR contact structure 25 having a second critical dimension width (CD2) that is between the buried dielectric via portion 19A and the S/D sidewall structure of the PFET device 30. In embodiments, the CD1 width of VBPR contact structure 25 ranges from between 25 and 70 nm and the CD2 width of VBPR contact structure 25 ranges from between 8 and 30 nm. The removal of one sidewall spacer portion from S/D sidewall and bottom spacers 21 allows fabrication of many FET devices of much smaller pitch yet still allows the VBPR contact structure 25 to maintain a larger CD1 which improves the VBPR resistance.

As further shown in FIG. 1A, isolated VBPR contact portion 25A of the PFET device 30 is further connected to a wiring and/or metal line structure 32 formed during back-end-of-line (BEOL) processing via an interconnect structure, e.g., a metal contact via 35.

As further shown in FIGS. 1, 1A, the underlying BPR 16 connects to S/D sidewall structures of a NFET device 50, however unlike for the PFET device 30, a formed second VBPR conductor structure 26 connects the underlying BPR 16 to both epitaxial grown source or drain (S/D) structures 18 of the NFET device 50. As further shown in FIG. 1A, the epitaxial grown S/D structures 18 also each include surrounding “asymmetric” S/D sidewall spacers 21 which are dielectric spacer structures having portions removed at opposing sides of the S/D structures 18 facing each other which allows space for the deposition of the VBBP contact structure 26 of CD1 connecting to sidewall of each S/D structure 18 for the NFET device 50.

FIG. 1B shows a cross-sectional view of the semiconductor structures 10 taken along the line X-X as shown in FIG. 1. In the view of FIG. 1B, there is depicted a PFET device 30 as including high-k metal gate (HKMG) structures 20 fabricated using known Replacement Metal Gate (RMG) processing techniques. As shown in FIG. 1B taken along line X-X in FIG. 1, each formed PFET device 30 include asymmetric S/D sidewall spacers 21 present on one side of S/D sidewall including nanosheet channel layers 12. Between nanosheet layers 12 are inner spacers 42 of a low-k dielectric material, e.g., a nitride based material. For each HKMG structure 20, conformal high-k metal gate material 40 has been deposited to surround the nanosheet channel layers 12. As further shown in FIG. 1B, a further VBPR contact structure 25 of the PFET device 30 is further connected to a wiring and/or metal line structure 32 formed during back-end-of-line (BEOL) processing via a further interconnect structure, e.g., a metal contact via 36.

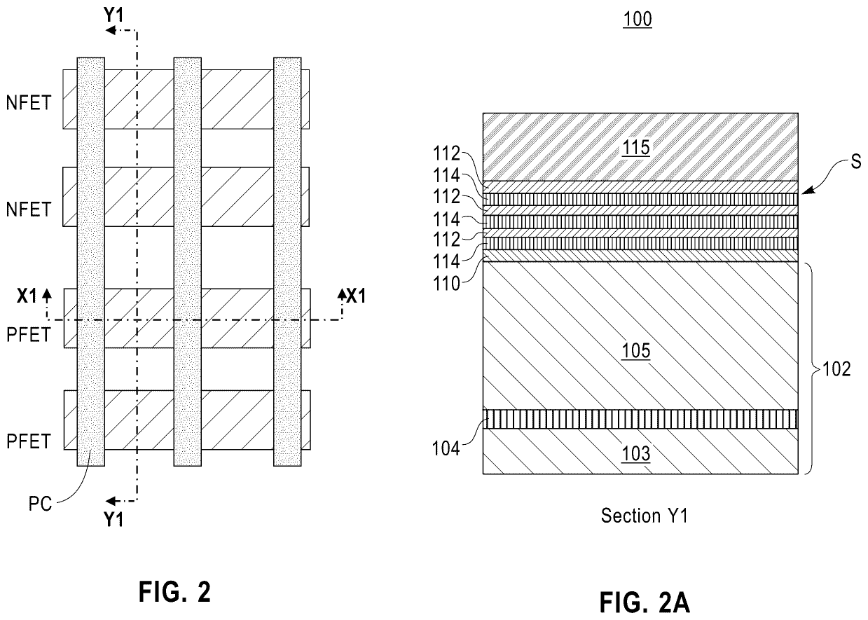

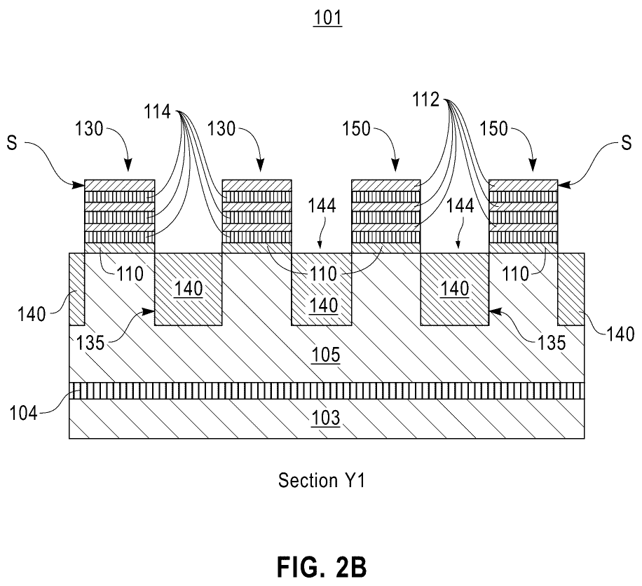

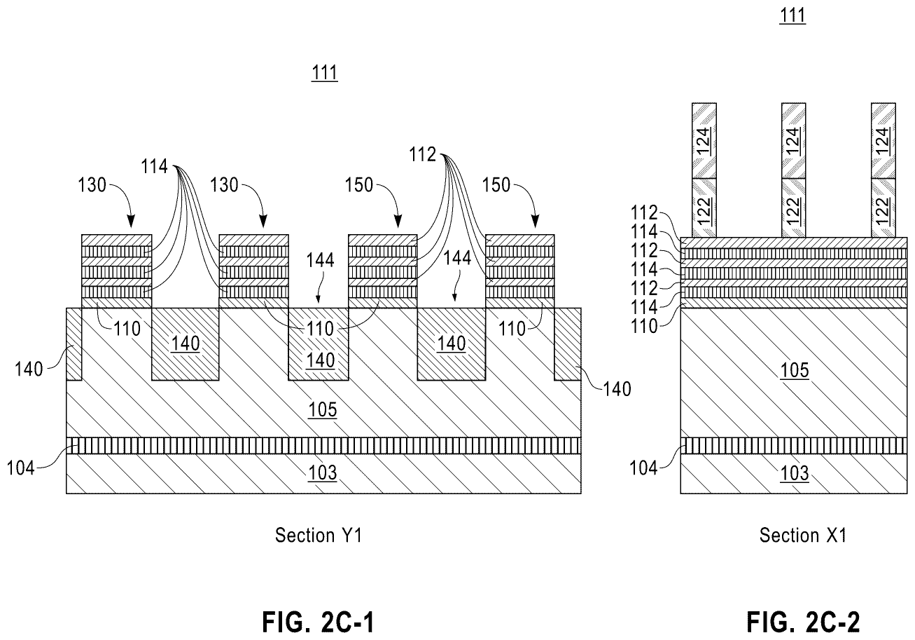

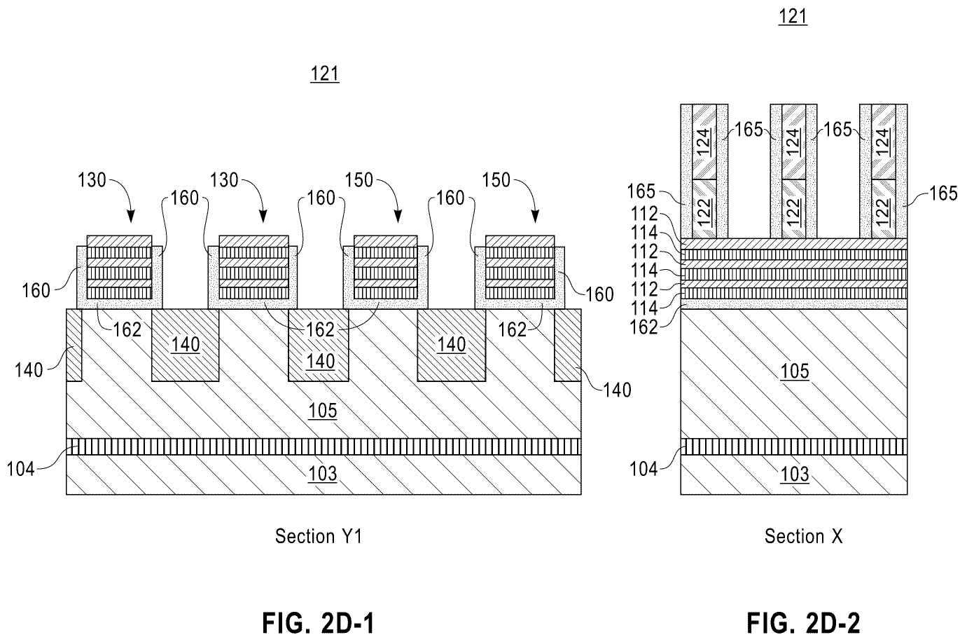

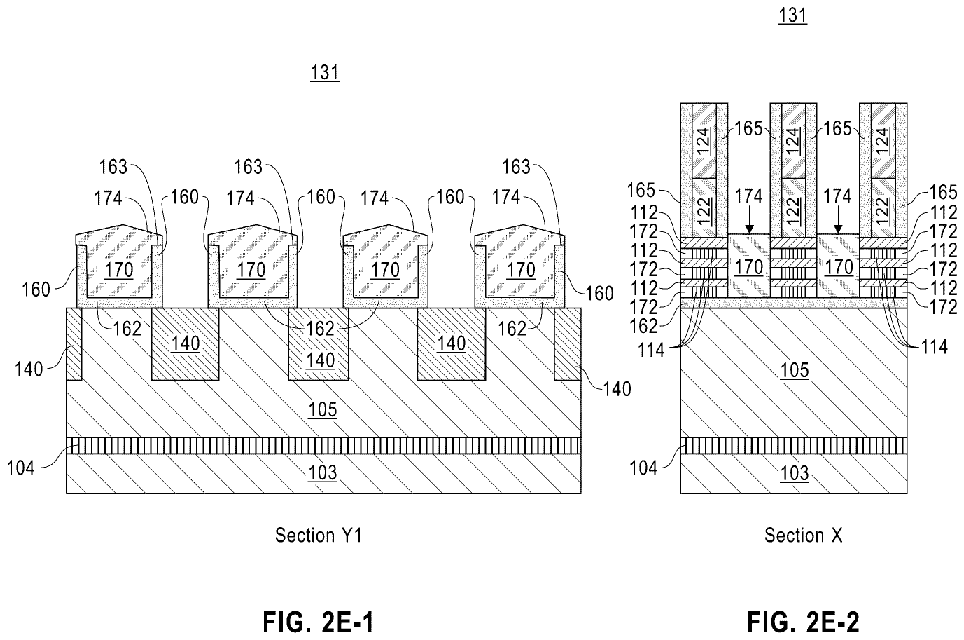

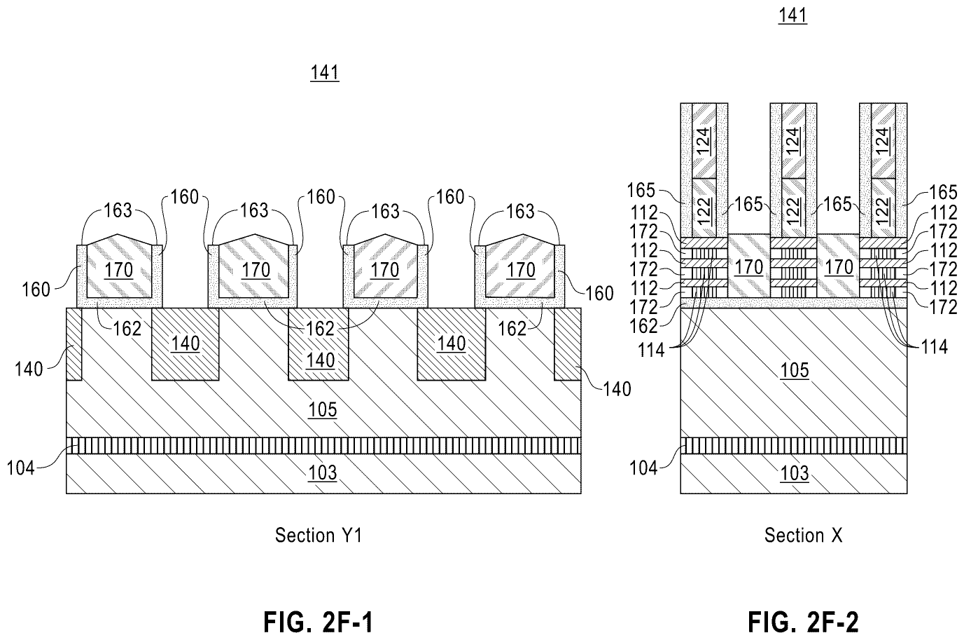

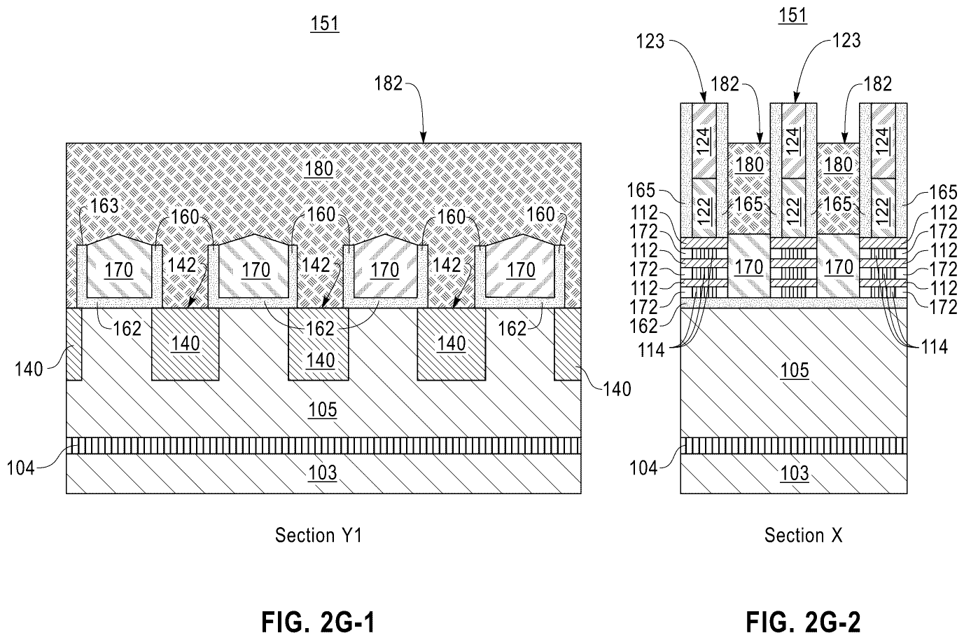

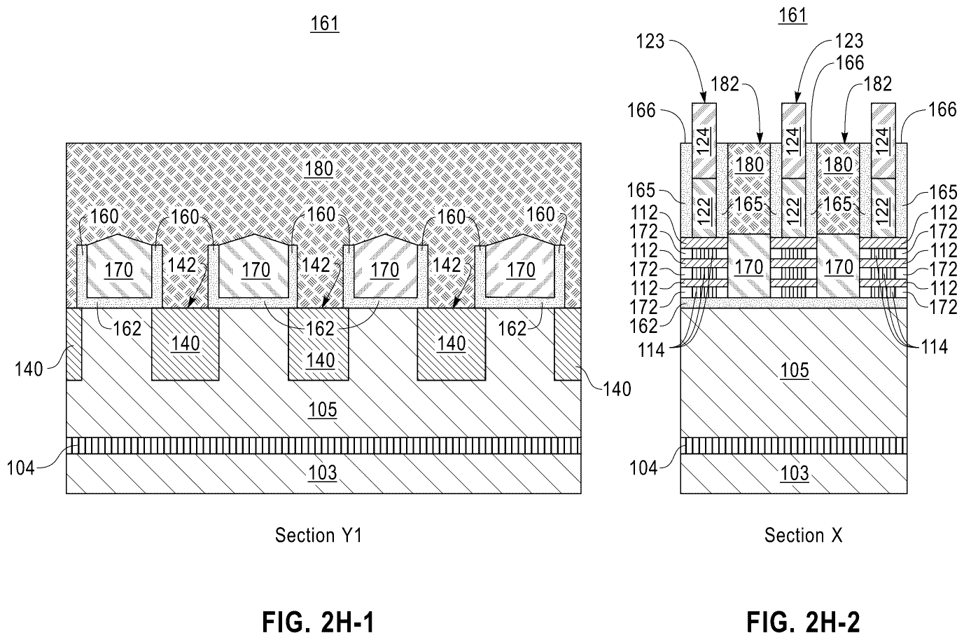

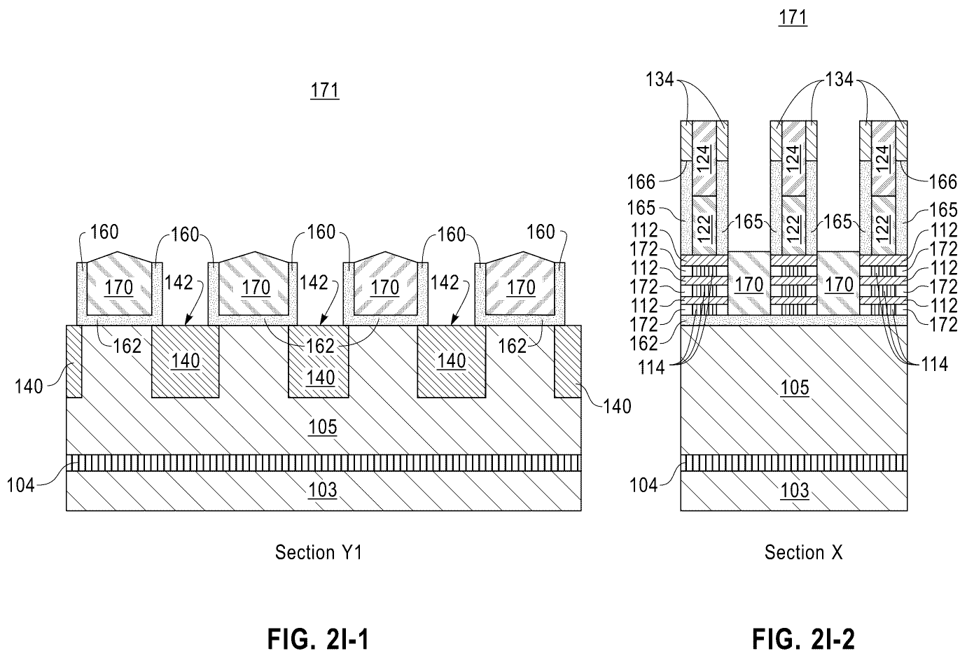

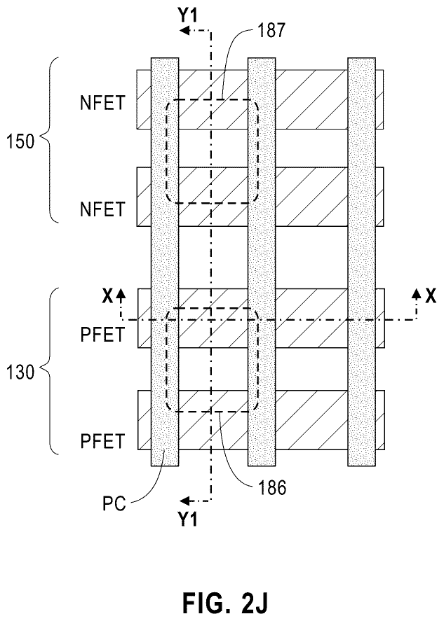

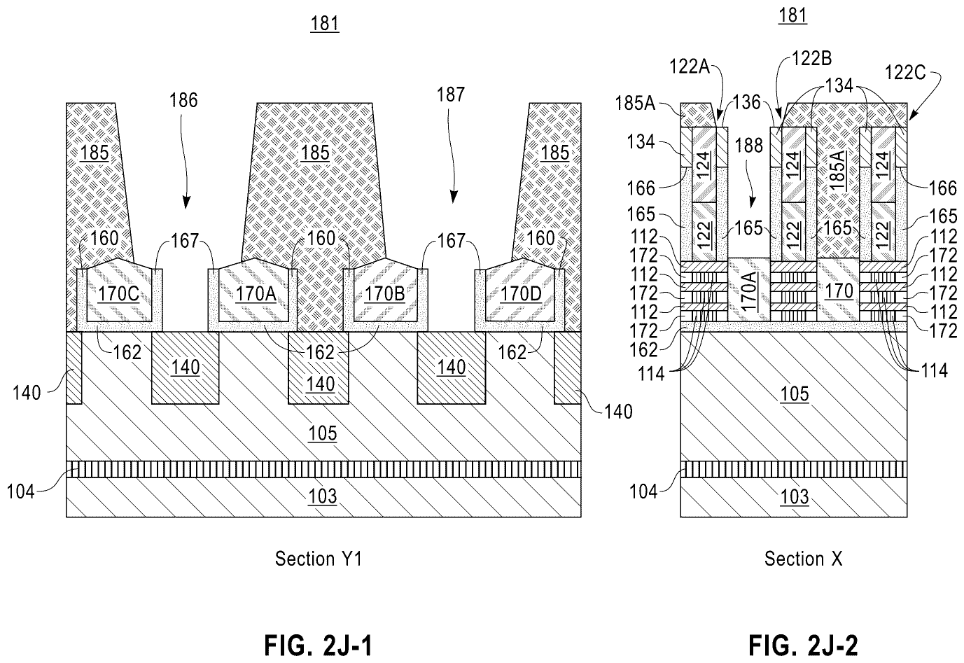

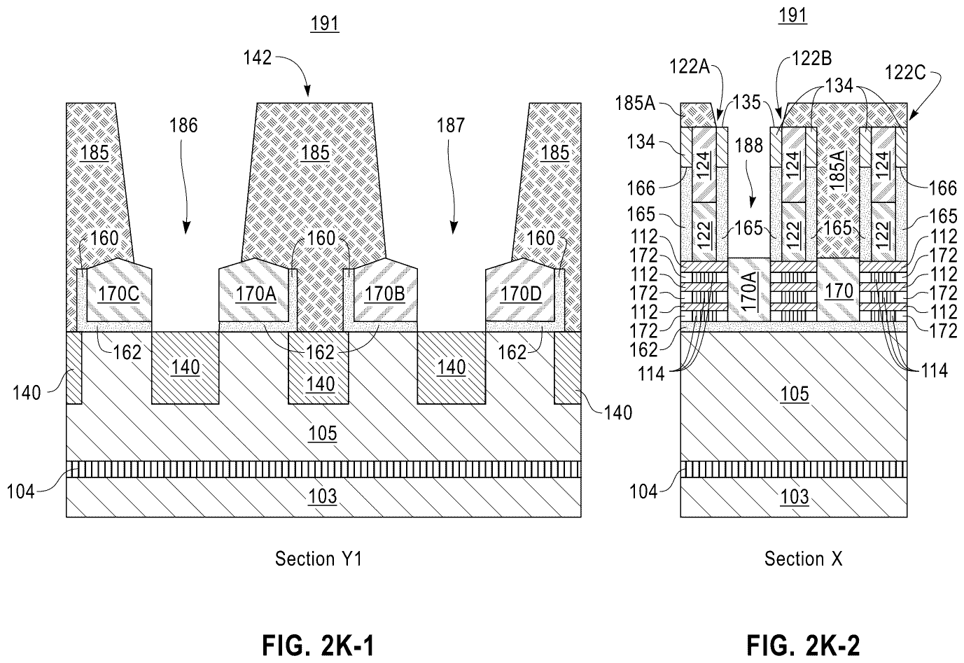

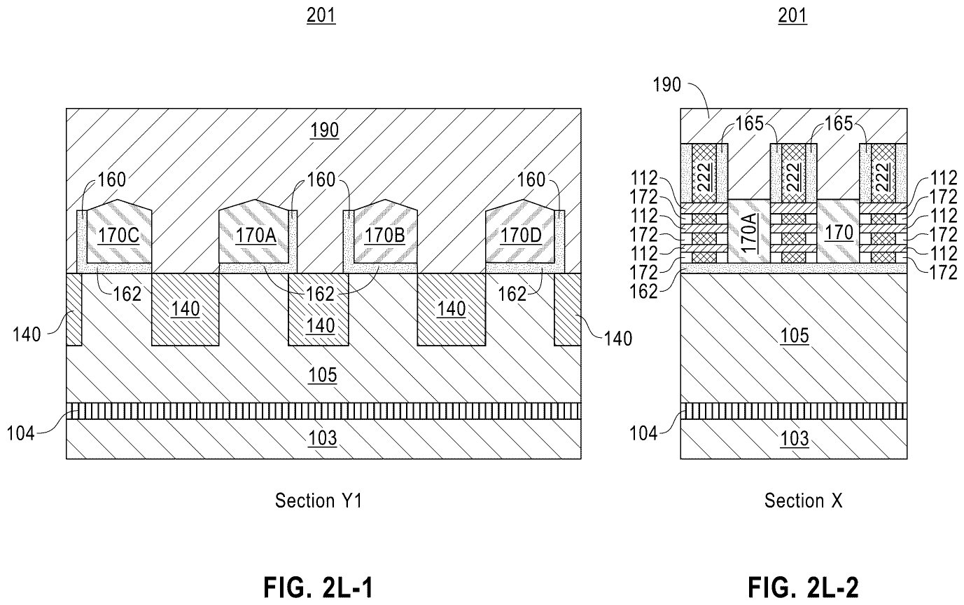

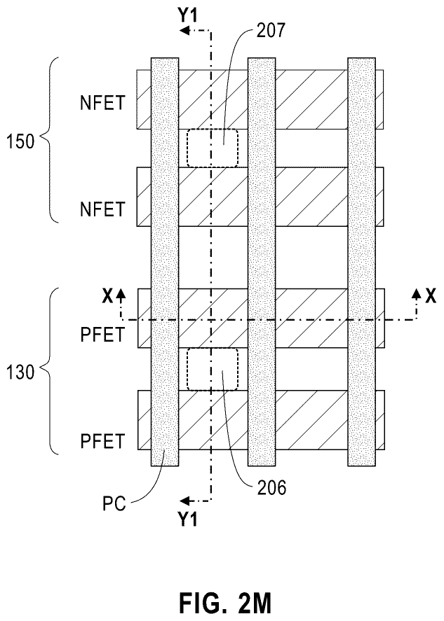

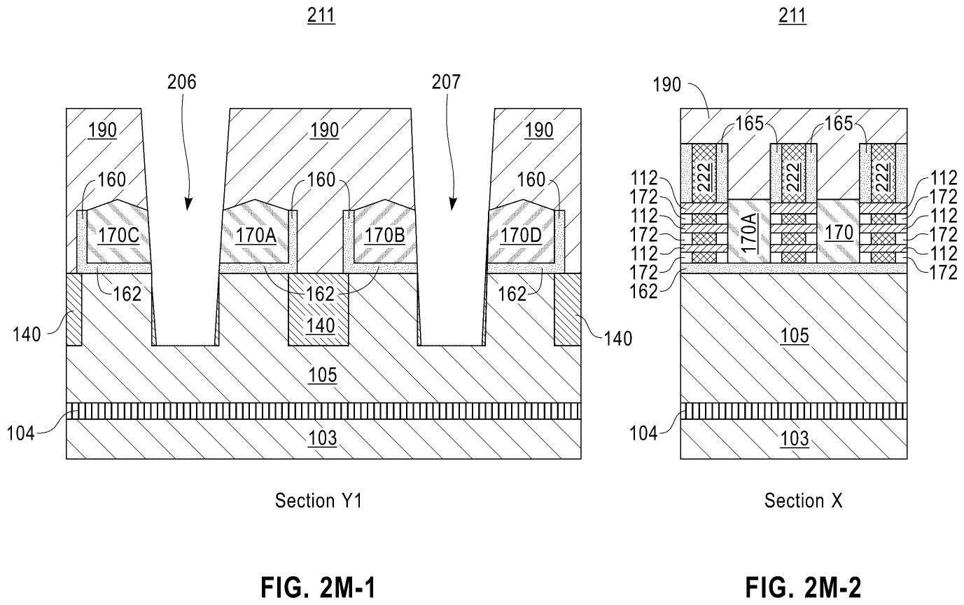

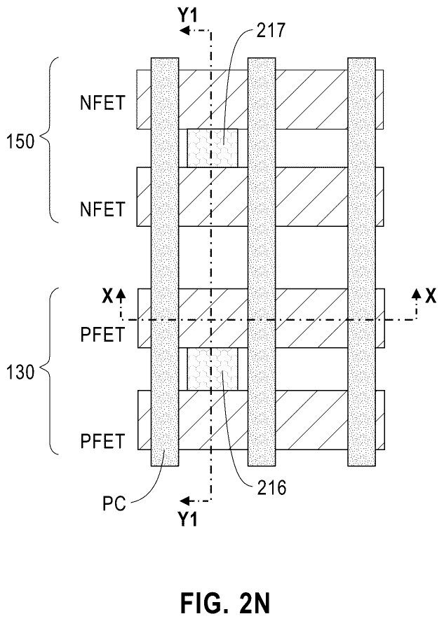

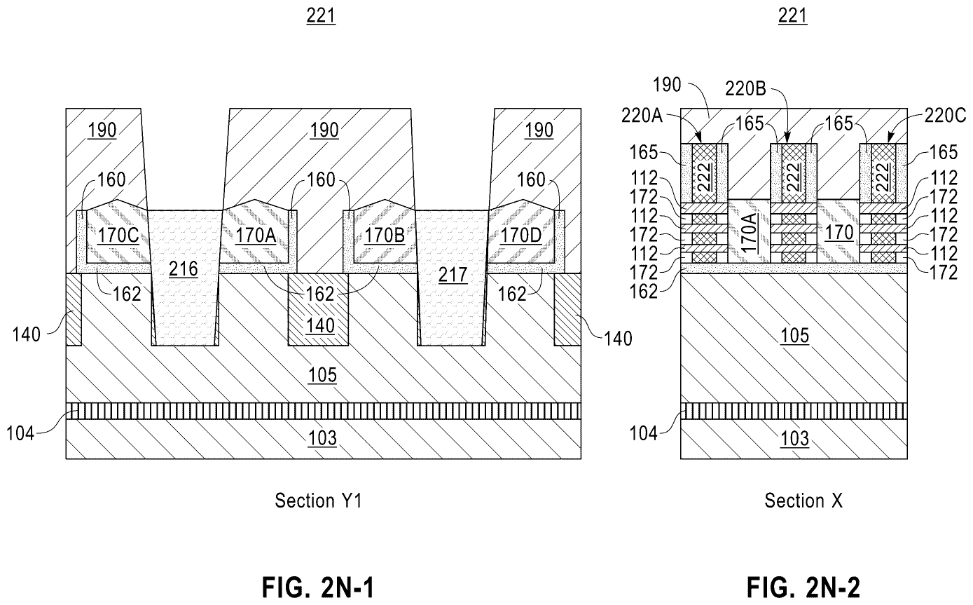

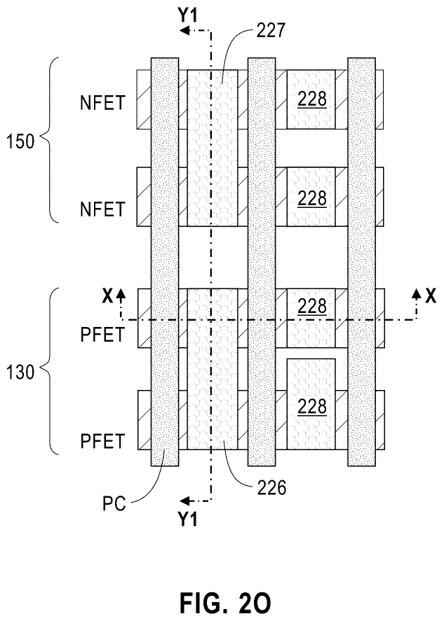

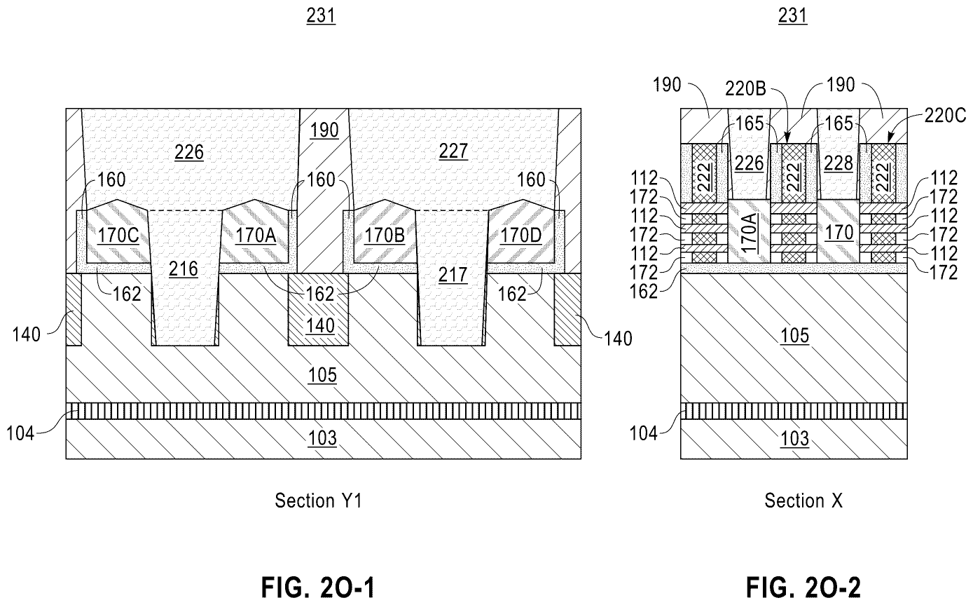

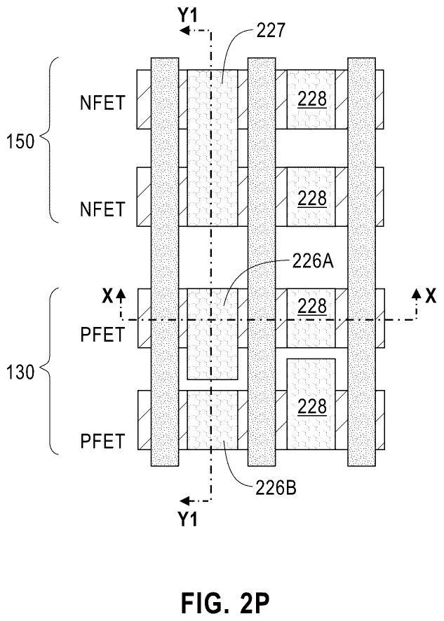

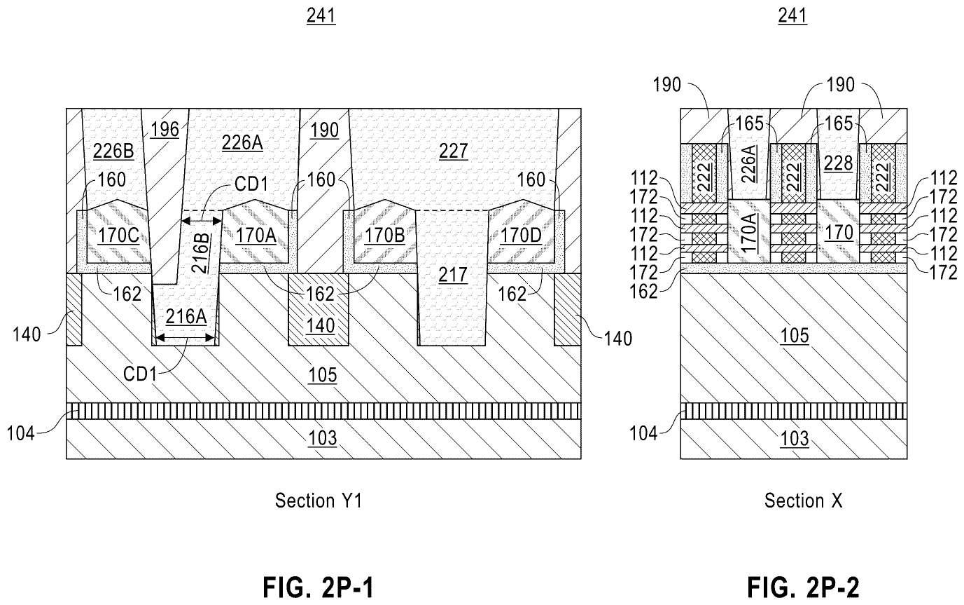

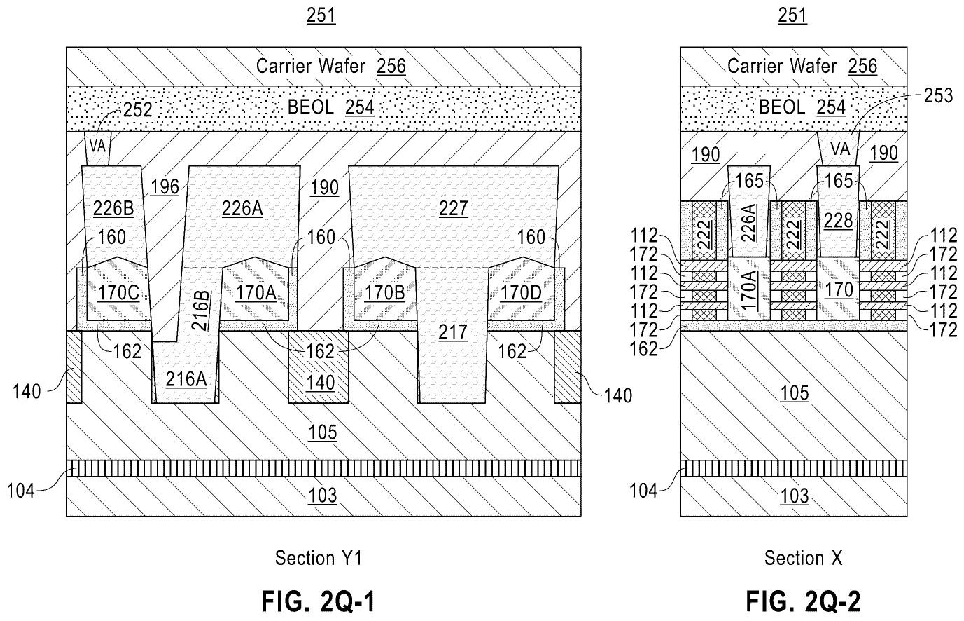

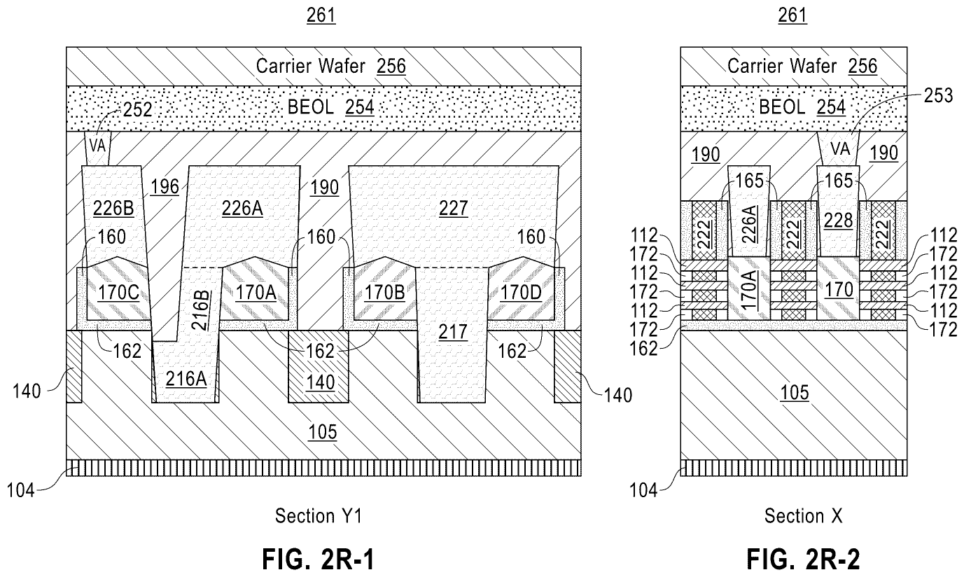

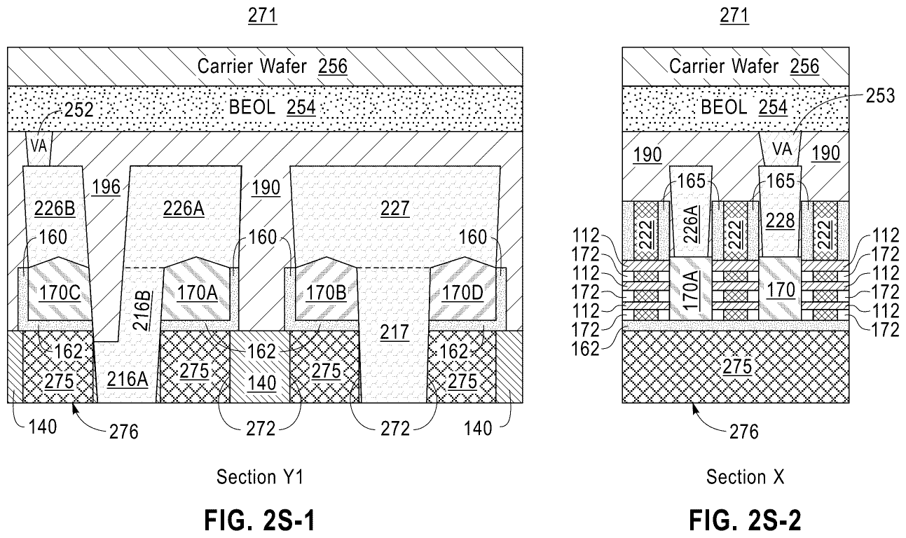

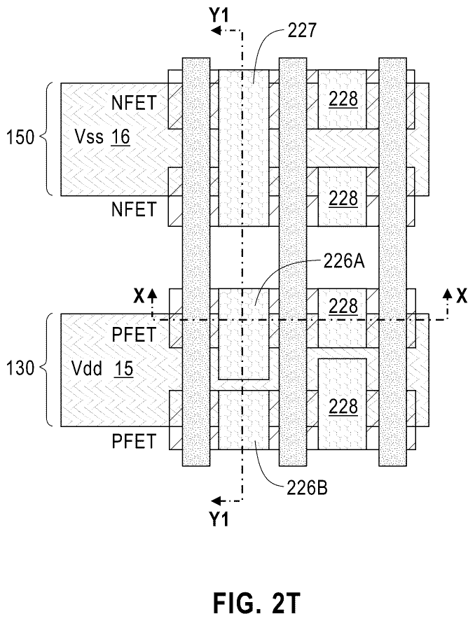

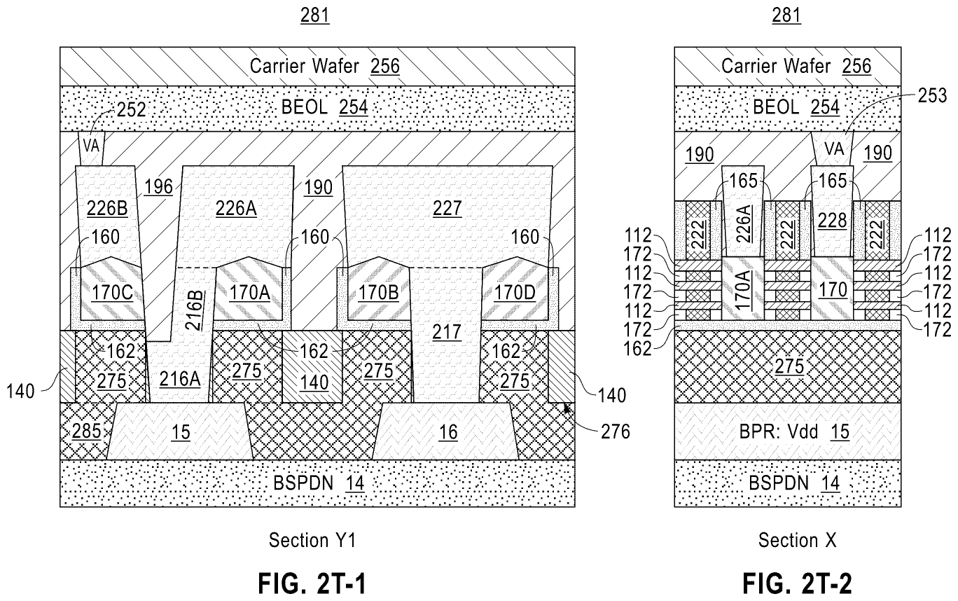

FIGS. 2A, 2B, . . . , 2T-1, 2T-2 depict the method steps for forming improved VBPR contact structures 25, 25A of FIGS. 1, 1A, 1B that connect to respective adjacent vertical stacked GAA NS semiconductor pFET devices 30.

FIG. 2 depicts a top down view indicating a layout on a wafer substrate of locations on which semiconductor structures including stacked GAA NS FET structures including asymmetric source/drain spacers and shifted VBPR structures are formed according to embodiments of the present disclosure.

Referring to FIG. 2A, there is illustrated an initial semiconductor structure 100 at an early stage of fabrication in accordance with an embodiment of the present disclosure. The cross-sectional view depicted in FIG. 2A is taken along line Y1-Y1 of a top-down layout view of FIG. 2. Notably, the exemplary initial semiconductor structure 100 of FIG. 2A is built on a wafer semiconductor material substrate 102 (“substrate 102”) of a first wafer having, the substrate including a thin dielectric etch stop layer 104 dividing the substrate 102 into bottom substrate portion 103 and top substrate portion 105 above etch stop layer 104. The substrate 102 including top substrate portion 105 could be Si or SiGe or other high mobility channel material, e.g., GaAs. In an embodiment, the etch stop layer 104 on the bottom substrate portion 103 can be a layer of SiGe functioning as an etch stop.

Formed on top substrate portion 105 of the wafer is a thin layer 110 of sacrificial SiGe material such as SiGe55% (wherein Ge concentration is 55%). Thin layer 110 ranges from between 3 nm to 15 nm thick. Formed on thin layer 110 of SiGe55 is a semiconductor material nanosheet (NS) stack, S, of alternating NS layers of: semiconductor material layers 112 that will form the channels of the GAA NS FET structures and a sacrificial semiconductor material layer(s) 114. In the embodiment depicted, the NS stack S of alternating semiconductor material layers 112 and sacrificial semiconductor material layers 114 are formed atop the top substrate portion 105 made of silicon.

As further shown in FIG. 2A, formed above NS stack S is a top insulating hardmask layer 115 formed of a nitride material, oxide material and/or a combination of oxide and nitride materials. This top insulating hardmask layer 115 is patterned using semiconductor lithography to define device nanosheet channels out of NS stack S and define shallow trench isolation region structures to be formed therebetween.

In embodiments, the substrate 102 provides mechanical support for the overlying semiconductor material layers 112 and sacrificial semiconductor material layers 114 of NS stack S. The substrate 102 may include any semiconductor material including, for example, silicon. The term “semiconductor material” is used throughout the present disclosure to denote a material that has semiconducting properties. Besides silicon, the semiconductor material may be germanium (Ge), a silicon germanium alloy (SiGe), silicon carbide (SiC), silicon germanium carbide (SiGeC), III-V compound semiconductors or II-VI compound semiconductors such as GaN, GaAs, InP, and InAs, etc.

The etch stop layer 104, which in some embodiments may be referred to as a buried insulator layer, may be a crystalline, or non-crystalline, oxide or nitride. In one embodiment, the insulator layer is an oxide such as, for example, silicon dioxide.

In an embodiment, rather than providing an etch stop layer 104, the wafer may include a Silicon-On-Insulator (SOI) substrate upon which the semiconductor material stack S is formed.

On the wafer, the semiconductor material stack(S) is then sequentially formed upon the top substrate portion 105. As mentioned above, the semiconductor material stack includes semiconductor material layers 112, and sacrificial semiconductor material layers 114 which alternate one atop the other. The semiconductor material stack can be formed by sequential epitaxial growth of alternating layers of the first semiconductor material and the sacrificial semiconductor material. In FIG. 2A, and by way of one example, the semiconductor material stack includes three alternating layers of the semiconductor material layers 112 and sacrificial semiconductor material layers 114. The semiconductor material stack S that can be employed in the present disclosure are not limited to the specific embodiment illustrated in the figures. Instead, the semiconductor material stack can include any number of the semiconductor material layers 112 and corresponding sacrificial semiconductor material layers 114 so long as the semiconductor material stack includes at least two semiconductor material layers 112, alternating with two sacrificial semiconductor material layers 114.

Each semiconductor material layer 112 is composed of a semiconductor material which can be the same or differ in composition from the top substrate portion 105. In one embodiment, the top substrate portion 105 is composed of silicon, while each semiconductor material layer 112 is also composed of silicon. In such an embodiment, the sacrificial semiconductor material layers 114 can be a SiGe alloy, e.g., SiGe30% (e.g., 30% Ge content). In embodiments, each semiconductor material layer 112 can be composed of a silicon germanium alloy and the sacrificial semiconductor material layers 114 can be Si. In embodiments, the silicon germanium alloy providing the sacrificial/semiconductor material layer has a germanium content that is less than 75 atomic percent germanium. In one example, the silicon germanium alloy that provides each sacrificial/semiconductor material layer has a germanium content from 20 atomic percent germanium to 40 atomic percent germanium. The first semiconductor material that provides each semiconductor material layer 112 can be formed utilizing an epitaxial growth (or deposition process) as defined in greater detail herein below.

In embodiments, each sacrificial semiconductor material layer 114 is composed of a second semiconductor material that has a different etch rate than (is different from) the first semiconductor material that provides the semiconductor material layers 112.

In a further example, the sacrificial semiconductor material layer 114 is composed of Si or a III-V compound semiconductor, while each semiconductor material layer 112 is composed of a silicon germanium alloy. The second semiconductor material that provides each sacrificial semiconductor material layer 114 can be formed utilizing an epitaxial growth (or deposition process) as defined in greater detail herein below.

The terms “epitaxially growing and/or depositing” and “epitaxially grown and/or deposited” mean the growth of a semiconductor material on a deposition surface of a semiconductor material, in which the semiconductor material being grown has the same crystalline characteristics as the semiconductor material of the deposition surface. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same crystalline characteristics as the deposition surface on which it is formed.

Examples of various epitaxial growth process apparatuses that can be employed in the present disclosure include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition typically ranges from 550° C. to 900° C. Although higher temperature typically results in faster deposition, the faster deposition may result in crystal defects and film cracking. The epitaxial growths described herein can be performed utilizing any well known precursor gas or gas mixture. Carrier gases like hydrogen, nitrogen, helium and argon can be used.

Each semiconductor material layer 112 can have a thickness ranging from between 5 nm to 12 nm, while each sacrificial semiconductor material layer 114 can have a thickness from 3 nm to 12 nm.

In further view of FIG. 2A, a top insulating hardmask layer 115 is deposited upon a top semiconductor material layer 112. The top insulating hardmask layer 115 can comprise an oxide, e.g., SiO₂, or an oxynitride and can be deposited to a thickness ranging between 5 nm and 100 nm.

FIGS. 2B-2D depict method steps for forming a vertically stacked dummy gate structures surrounding the stack S of multiple, horizontal stacked nano-sheet channel layers for GAA NS PFET and NFET structures being formed.

In view of FIG. 2B, there is depicted a resulting intermediate structure after conducting a series of processing steps upon the initial semiconductor structure 100 of FIG. 2A. FIGS. 2, 2B particularly depict a cross-sectional view of an intermediate structure 101 taken along line Y1-Y1 resulting after performing a process which includes lithographic patterning and etching processes to provide multiple GAA NS pFET device channel structures 130 and GAA NS nFET device channel structures 150. The lithographic step can include forming layer of a photoresist (not shown) atop the top insulating hardmask layer 115, exposing the photoresist to a desired pattern of radiation and then developing the exposed photoresist utilizing a conventional resist developer. The pattern within the photoresist is then transferred through the top insulating hardmask layer 115 and into the underlying alternating layer nanosheet stack S. A single etch or multiple etching can be used to provide the resulting multiple pFET device channel structures 130 and nFET device channel structures 150 of intermediate structure 101 illustrated in FIG. 2B. The etch or multiple etch can include a dry etch process, a chemical wet etch process, or any combination thereof. When a dry etch is used, the dry etch can be a reactive ion etch process, a plasma etch process, ion beam etching or laser ablation. The patterned photoresist material can be removed any time after transferring the pattern into at least the hardmask utilizing a conventional stripping process. As a result of performing lithographic patterning and etching the width of the semiconductor material nanosheet stack of multiple, horizontal stacked nano-sheet channel layers is defined for forming the gate all-around FET structure of the NS FETs (nanosheet FETs).

Further referring to FIG. 2B, after lithographic patterning (not shown) of the top insulating hardmask layer 115 and a further etching of stack S to form individual stacked nanosheet pFET device channel structures 130 for GAA NS PFET devices to be formed and stacked NS nFET device channel structures 150 for GAA NS NFET devices to be formed. Each individual formed stack of channel structures is separated from each other by a recess 144 therebetween. Beneath each recess 144 there is further formed STI structures 140 to isolate the formed nanosheet channel structures of the pFET and nFET devices being formed. STI structures 140 can be formed by etching the top substrate portion 105 using photolithography techniques to form trenches 135. Generally, photolithography involves depositing a photoresist material, which is then masked, exposed, and developed. After the photoresist mask is patterned, an etching process can be performed to remove unwanted portions of the top substrate portion 105. In an embodiment in which top substrate portion 105 includes bulk silicon, the etching process can be a wet or dry, anisotropic or isotropic, etch process. The trenches 135 are then filled with a dielectric material such as an oxide layer formed by any oxidation process, such as wet or dry thermal oxidation in an ambient comprising an oxide, H2O, NO, or a combination thereof, or by chemical vapor deposition (CVD) techniques using tetra-ethyl-ortho-silicate (TEOS) and oxygen as a precursor. In an embodiment, the lithographic patterning and etching steps are implemented to etch a pattern of recesses 144 in the stack S and corresponding trenches 135 in the top substrate portion 105, each etch forming a recess and trench between and separating each pFET device channel structures 130 and nFET device channel structures 150. The trenches 135 are then deposited with one or more dielectric materials, e.g., SiO₂ to fill the trenches and form the shallow-trench-isolation structures 140 between each pFET device channel structure 130 and nFET device channel structure 150. The hardmask layer is then removed to result in the formed intermediate structure 101 shown in FIG. 2B.

Referring to FIGS. 2C-1, 2C-2 there is illustrated a resulting intermediate semiconductor structure 111 taken along line Y1-Y1 of FIG. 2 after layer patterning and deposition steps to form dummy gate structures 122 that surround the stack S2 of multiple, horizontal stacked nano-sheet channel layers. FIG. 2C-2 depicts the resulting intermediate semiconductor structure 111 taken along line X1-X1 of FIG. 2 after layer patterning and deposition steps to form the dummy gate structures 122. Each dummy gate structure 122 can be formed by blanket depositing dummy (sacrificial) gate material such as a thin layer of oxide and amorphous silicon and an overlying hardmask layer 124 and then a lithographic patterning and etching process is done to form the dummy gate structures 122.

Referring to FIG. 2D-1, there is illustrated a resulting intermediate semiconductor structure 121 taken along line Y1-Y1 of FIG. 2 after etching steps to selectively remove the thin layer 110 underlying each individual stacked nanosheet pFET device channel structures 130 for GAA PFET devices to be formed and stacked NS nFET device channel structures 150 for GAA NFET devices to be formed. The selective removal of thin layer 110 creates an opening underneath each pFET device and nFET device channel structures 130, 150. It is noted that the nanosheet stacks are not floating but are anchored to the formed dummy gate structures 122. The removal of the thin layer 110 is created in preparation for forming a bottom dielectric isolation layer which is to isolate the source and drain regions to be formed for the GAA NS FETs. Thus, subsequent steps include further depositing dielectric material to form S/D sidewall spacers 160 surrounding the bottom and side surfaces of each individual stacked nanosheet pFET device channel structure 130 for GAA PFET devices to be formed and surrounding the bottom and side surfaces of each individual stacked NS nFET device channel structure 150 for GAA NFET devices to be formed. Additionally formed at the bottom of each stacked pFET device channel structure 130 and stacked nFET device channel structure 150 and source and drain regions to be formed is a bottom dielectric isolation (BDI) dielectric material layer 162. This structure is also referred to as a Self Aligned Substrate Isolation (SASI). That is, a full BDI dielectric material layer 162 is formed beneath each individual stacked pFET device channel structure 130 for GAA PFET devices to be formed and each stacked nFET device channel structure 150 for GAA NFET devices to be formed when dielectric material to form S/D sidewall spacers 160 is conformally deposited. FIG. 2D-2 shows the resulting intermediate semiconductor structure 121 taken along line X1-X1 of FIG. 2 after removing the thin layer 110 and depositing source/drain sidewall dielectric spacers at sidewalls of the formed pFET device and nFET device channel structures 130, 150 that include forming of dummy gate dielectric sidewall spacers 165 at each sidewall of each dummy gate structure 122. Subsequent planarization steps result in a top surface of the sacrificial overlying hardmask layer 124 co-planar with a top surface of each dummy gate dielectric sidewall spacer 165. Further shown is the deposition of BDI dielectric material layer 162 beneath each individual stacked nanosheet pFET device channel structures 130 for GAA PFET devices to be formed and stacked NS nFET device channel structures 150 for GAA NFET devices to be formed. The benefits of BDI layer in a SASI process is to reduce sub-channel leakage and provide increased immunity to process variations and power-performance improvement.

Referring to FIG. 2E-1, there is illustrated a resulting intermediate semiconductor structure 131 taken along line Y1-Y1 of FIG. 2 after processing steps to recess edges of each individual stacked nanosheet pFET device channel structures 130 for GAA PFET devices to be formed and stacked nFET device channel structures 150 for GAA NFET devices to be formed. The structure 131 results after forming inner dielectric spacers (inner spacers) and epitaxially growing source and drains for each respective GAA PFET and NFET devices to be formed. As shown in FIG. 2E-1, as a result of lithographic patterning and etching processes, recesses are formed along at sidewall edges of each pFET device channel structure 130 and nFET device channel structures 150. FIG. 2E-1 shows the epitaxial deposition of the S/D structure 170 that includes a top S/D epi edge structure 174 having extended portions that overlap top edge surface 163 of each of the S/D sidewall spacers 160 surrounding the individual stack. FIG. 2E-2 shows the resulting intermediate semiconductor structure 131 taken along line X1-X1 of FIG. 2 after processing steps to form recesses into sacrificial material layers 114 of each nanosheet (NS) stack, the forming of inner dielectric spacers 172 at those pulled locations and the epitaxial growing of source or drain (S/D) structures 170 for each pFET and nFET between each dummy gate structure 122 as shown in FIG. 2E-2. The recesses into sacrificial material layers 114 and forming of inner spacers 172 at this stage will permit only just the Si NS semiconductor material layers 112 to remain connected to the S/D structures 170.

Referring to FIG. 2F-1, there is illustrated a resulting intermediate semiconductor structure 141 taken along line Y1-Y1 of FIG. 2 after processing steps to trim the source and drain structures 170 to remove portions of the top overlapping S/D epi edge structure 174 and reveal the top edge surface 163 of the S/D sidewall spacers 160 at each stacked nanosheet pFET device channel structure 130 for GAA pFETs and stacked nanosheet nFET device channel structures 150 for GAA nFETs to be formed. As shown in FIG. 2F-1, as a result of lithographic pattern and etching processes, the semiconductor source and drain structures 170 are trimmed. FIG. 2F-2 shows the resulting intermediate semiconductor structure 141 taken along line X1-X1 of FIG. 2 after processing steps to trim the source and drain structures 170 and reveal sidewall spacers at each GAA NS pFET and GAA NS nFET.

Referring to FIG. 2G-1, there is illustrated a resulting intermediate semiconductor structure 151 taken along line Y1-Y1 of FIG. 2 after processing steps to pattern and deposit a top organic planarization layer (OPL) 180 of a dielectric material on top of the structures depicted in FIGS. 2F-1 and 2F-2. Such an OPL is shown subsequently etched or recessed to form the OPL 180 having a top surface 182 that is below the top surface 123 of the dummy gate structures 122 of the GAA NS pFET and nFET gate structures to be formed. FIG. 2G-2 shows the resulting intermediate semiconductor structure 151 taken along line X1-X1 of FIG. 2 after processing steps to pattern a photoresist mask defining an area for depositing an OPL layer and then etching back, using wet etch or dry etching such as a Reactive Ion Etch (RIE) of the OPL 180 such that its top surface 182 is at a level below a top surface 123 of dummy gate structure 122. As shown in FIG. 2G-2, the top surface is recessed approximately in a range from 10 nm to 50 nm below the top surface 123 of dummy gate structures 122 of the GAA NS pFETs and GAA NS nFETs. The deposition of the OPL 180 is performed to enable subsequent removal of portions of dummy gate dielectric sidewall spacer 165 around the dummy gate structure 122.

Referring to FIG. 2H-1, there is illustrated a resulting intermediate semiconductor structure 161 taken along line Y1-Y1 of FIG. 2 after processing steps to pattern a mask (not shown) and etch to remove the portions of dummy gate dielectric sidewall spacers 165 that were exposed above the top surface 182 of the organic planarization layer (OPL). As a result, the dummy gate dielectric sidewall spacers 165 are recessed, e.g., by dry etching selective to the OPL 180, to expose the dummy gate overlying hardmask layer 124. As a result, the exposed top surfaces 166 of the dummy gate dielectric sidewall spacer 165 are at the same level as the top surface 182 of the OPL layer 180. FIG. 2H-2 shows the resulting intermediate semiconductor structure 161 taken along line X1-X1 of FIG. 2 after processing steps to pattern a photoresist mask (not shown) defining areas for etching the portions of dummy gate dielectric sidewall spacers 165 that are exposed above the top surface 182 of the OPL 180 such that dummy gate dielectric sidewall spacers 165 are recessed, e.g., by dry etching selective to the OPL 180 and dummy gate overlying hardmask layer 124. As shown in FIG. 2H-2, the recessing of the top portions of dummy gate dielectric sidewall spacers 165 result in exposed top surfaces 166 and exposes a top portion of each dummy gate overlying hardmask layer 124 at each of the GAA NS pFETs and GAA NS nFETs dummy gates.

Referring to FIG. 2I-1, there is illustrated a resulting intermediate semiconductor structure 171 taken along line Y1-Y1 of FIG. 2 after processing steps to lithographically pattern and deposit a gate protective dielectric material sidewall spacer 134 (gate protective spacer 134) atop the exposed top surfaces 166 of the dummy gate dielectric sidewall spacers 165 surrounding dummy gate structures 122. This protective layer can be SiC, SiO₂, AlOx, HfO₂, AlNx, and functions as a gate protective spacer 134 surrounding the exposed portions of sacrificial dummy gate overlying hardmask layer 124 at each GAA NS pFET and nFET dummy gate structure 122. Then, the OPL 180 is removed, e.g., via plasma ashing of the OPL material or a wet strip. Removal of the OPL 180 exposes top surfaces 142 at each STI structure formed in top substrate portion 105. FIG. 2I-2 shows the resulting intermediate semiconductor structure 171 taken along line X1-X1 of FIG. 2 after lithographic patterning and depositing processing steps to form gate protective spacers 134 surrounding the exposed dummy gate overlying hardmask layer 124. A CMP planarization step can be performed to co-planarize surface of the gate protective spacer and the surface of dummy gate overlying hardmask layer 124 at each dummy gate structure 122. FIG. 2I_2 further depicts the removal of the OPL 180.

FIG. 2J depicts the top layout view of the resulting intermediate semiconductor structures shown in FIG. 2 further indicating locations of openings 186, 187 for exposing S/D sidewall spacers to be pulled down. These openings 186, 187 are formed during a VBPR sidewall spacer “keep” patterning step to deposit dielectric material, an OPL dielectric material, for protecting specific S/D sidewall spacers 160 and exposing opposing S/D dielectric sidewall spacer portions 167 for removal of the structure shown in 2I-1. Referring to FIG. 2J-1, there is illustrated a resulting intermediate semiconductor structure 181 taken along line Y1-Y1 of FIG. 2J after processing steps to deposit, lithographically pattern and etch a dielectric material layer leaving dielectric layer portions 185 to protect or “keep” certain S/D sidewall spacers 160 of desired GAA NS pFET and nFET devices to be formed. As shown in the non-limiting example structures 181 depicted in FIG. 2J-1, using lithography, a patterned mask is formed and dielectric material layer deposited and etched to result in formed dielectric layer portions 185 according to a VBPR source/drain (S/D) spacer “keep” pattern to cover and protect selected S/D sidewall spacers 160 of the epitaxial grown S/D regions of the GAA NS FET devices being formed. For example, in FIG. 2J-1, a VBPR S/D spacer keep dielectric layer portion 185 is deposited to overly portions of adjacent S/D structures 170A, 170B and the exposed STI structure 140 therebetween in order to protect and prevent removal of respective S/D sidewall spacers 160 of the epitaxial grown S/D regions that face each other of adjacent GAA NS pFET device and GAA NS nFET device being formed. As further shown in FIGS. 2J, 2J-1, dielectric layer portion 185, e.g., an OPL material, have portions removed between adjacent S/D structures 170A, 170C of adjacent GAA NS pFET devices to be formed as indicated as opening 186. Similarly, a dielectric layer portion has been removed between adjacent S/D structures 170B, 170D of adjacent GAA NS nFET devices to be formed as indicated as opening 187. Thus, within opening 186 there remains exposed opposing S/D dielectric sidewall spacer portions 167 of adjacent S/D structures 170A, 170C of adjacent pFET devices to be formed and within opening 187 there remains exposed opposing S/D dielectric sidewall spacer portions 167 of adjacent S/D structures 170B, 170D of adjacent nFET devices to be formed. FIG. 2J-2 shows the resulting intermediate semiconductor structure 181 taken along line X1-X1 of FIG. 2J after lithographic patterning and depositing processing steps to deposit the VBPR source/drain (S/D) spacer “keep” patterning dielectric layer portions 185 formed atop both adjacent S/D structure 170A of GAA NS pFET device and adjacent S/D structure 170B of adjacent GAA NS nFET device. As shown in FIG. 2J-2, taken along line X1-X1 of FIG. 2J, the cross-sectional view of structure 181 shows a further VBPR S/D spacer keep dielectric layer portion 185A formed atop and covering surfaces of dummy gate overlying hardmask layer 124 of each successive dummy gate structure 122A, 122B and 122C formed along line X1-X1. However, between adjacent dummy gate structures 122A, 122B there is patterned an opening 188 leaving exposed top surface portions 136 of the formed gate protective spacers 134 facing each other. Otherwise, along line X1-X1, a VBPR S/D spacer keep dielectric layer portion 185A is deposited to completely fill the space between adjacent dummy gate structures 122B, 122C and extending to cover top surfaces of both dummy gate overlying hardmask layer 124 and gate protective spacers 134 of both dummy gate structures 122B, 122C while only leaving exposed top surface portion 136 of gate protective spacers 134 of dummy gate structure 122B facing the gate protective spacers 134 of dummy gate structure 122A.

Referring to FIG. 2K-1, there is illustrated a resulting intermediate semiconductor structure 191 taken along line Y1-Y1 of FIG. 2J after exposed S/D spacer pull down processing steps to etch and remove exposed opposing S/D dielectric sidewall spacer portions 167 within opening 186 of adjacent S/D structures 170A, 170C of respective adjacent pFET devices to be formed and further etch to remove exposed opposing S/D dielectric sidewall spacer portions 167 within opening 187 of adjacent S/D structures 170B, 170D of adjacent nFET devices to be formed. Any subtractive wet or dry etch can be performed to remove exposed S/D dielectric spacer portions 167 selective to the STI and epitaxial S/D structures. FIG. 2K-2 shows the resulting intermediate semiconductor structure 191 taken along line X1-X1 of FIG. 2 after exposed S/D spacer pull down processing steps.

Referring to FIG. 2L-1, there is illustrated a resulting intermediate semiconductor structure 201 taken along line Y1-Y1 of FIG. 2 after depositing an interlevel dielectric (ILD) layer 190, e.g., a low-k dielectric material such as, e.g., an oxide such as SiO₂ over the structures shown in FIG. 2J-1, 2J-2. In particular, first the OPL dielectric layer portions 185 are removed by OPL stripping (e.g., ash processing), and an ILD material layer is deposited using conventional ILD deposition techniques. As shown, after OPL layer removal, the ILD layer 190 is deposited to completely cover all the structures of FIG. 2K-1 and including covering the formed openings above the STI structures 140 and the opening above STI structure 140 within which remain “kept” S/D sidewall spacers 160. Thereafter, a planarization technique such as a CMP is performed to recess the surface of the ILD layer 190 until the dummy gate overlying hardmask layer 124 is reached. FIG. 2L-2 shows the resulting intermediate semiconductor structure 201 taken along line X1-X1 of FIG. 2 after the OPL ash strip and the ILD 190 deposition and planarization steps. The resulting intermediate semiconductor structure 201 of FIG. 2L-2 further depicts the resulting structure after further processing steps to remove the dummy gate material structure 122 of oxide and amorphous Si and overlying hardmask layer 124 and removal of the sacrificial semiconductor material layers 114 and form high-k metal gate (HKMG) structures using Replacement Metal Gate (RMG) process techniques. In the performed RMG process flow, the dummy gate overlying hardmask layer 124 is removed and an etch is performed to remove the dummy gate material structure 122 (e.g., oxide and amorphous-Si). The remaining portions of the sacrificial semiconductor material layers 114 are selectively etched and removed to release the Si semiconductor material layers 112, e.g., using vapor phase HCl to remove the sacrificial semiconductor material layers 114 from the stack. The selective etch of the sacrificial semiconductor material layers 114 provides suspended, vertically spaced apart semiconductor material layer 112 remaining from the stack and creates openings between the semiconductor material layers 112. The remaining semiconductor material layers 112 form the channel regions for the subsequently formed devices. Then, high-k dielectric material metal gate (HKMG) layers 222 are conformally deposited according to known techniques. The HKMG layers 222 fill the previous locations of the sacrificial semiconductor material layers 114, so as to wrap around the semiconductor material layers 112 to form replacement metal gate structures for the GAA NS pFETs and GAA NS nFETs being formed. Optionally, a metal layer (not shown) can be formed on top of the HKMG layers 222.

In an embodiment, using a vapor deposition process, there is formed a layer of high-k dielectric material (e.g., Hafnium oxide) surrounding and encapsulating each horizontal, spaced apart nano-sheet forming the semiconductor material layers 112. As referred to herein, high-k gate dielectric material is a dielectric material having a dielectric constant greater than silicon dioxide. Exemplary high-k dielectrics include, but are not limited to, HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, SiON, SiNₓ, a silicate thereof, and an alloy thereof. Each value of x is independently from 0.5 to 3 and each value of y is independently from 0 to 2. In some embodiments, a multilayered gate dielectric structure comprising different gate dielectric materials, e.g., silicon dioxide, and a high-k gate dielectric, can be formed and used as the gate dielectric material. The gate dielectric material can be formed by any deposition process including, for example, chemical vapor deposition (CVD), plasma enhanced chemical vapor deposition (PECVD), physical vapor deposition (PVD), sputtering, or atomic layer deposition. In one embodiment of the present disclosure, the deposited gate dielectric material can have a thickness in a range from 1 nm to 10 nm. Other thicknesses that are lesser than, or greater than, the aforementioned thickness range can also be employed for the gate dielectric material.

Further, in an embodiment, additional RMG process steps including the replacing the dummy gate structure 122, e.g., with a valence band edge work function metal to form the HKMG layers 222 spanning across and surrounding formed NS channels. Example work function metals for the NS pFET transistor can include but are not limited to: metals selected from Pt, Rh, Ir, Ru, Cu, Os, Be, Co, Pd, Te, Cr, Ni, TiN, TiAl, TiAlC and alloys thereof.

FIG. 2M depicts the top layout view of the resulting intermediate semiconductor structures shown in FIG. 2 further indicating locations of trench openings 206, 207 for VBPR patterning after performing an ILD etch to open areas VBPR material deposition according to embodiments of the present disclosure. Referring to FIG. 2M-1, there is illustrated a resulting intermediate semiconductor structure 211 taken along line Y1-Y1 of FIG. 2M after VBPR pattern processing steps to lithographically pattern a mask defining VBPR trench openings 206, 207 and then etching to form VBPR trench opening 206 at the location where the opposing S/D sidewall dielectric spacer portions 167 have been removed from the adjacent S/D structures 170A and 170C of the adjacent pFET devices being formed and similarly where etched VBPR trench opening 207 is formed at the location where the opposing S/D dielectric sidewall spacer portions 167 have been removed from the adjacent S/D structures 170B and 170D of the adjacent nFET devices being formed. As shown in FIG. 2M-1, the etching of VBPR trench opening 206 extends down to remove the dielectric STI structure 140 between the adjacent S/D structures 170A and 170C and etching of VBPR trench opening 207 extends down to remove the STI structure 140 between the adjacent S/D structures 170B and 170D. The etching of VBPR patterned openings is a dry RIE process selective to the S/D epi spacers. FIG. 2M-2 shows the resulting intermediate semiconductor structure 211 taken along line X1-X1 of FIG. 2M after lithographic VBPR patterning and etching process selective to the S/D epi spacers.

FIG. 2N depicts the top layout view of the resulting intermediate semiconductor structures shown in FIG. 2 further indicating locations of VBPR structures 216, 217 resulting from VBPR patterning and VBPR metal material deposition according to embodiments of the present disclosure. Referring to FIG. 2N-1, there is illustrated a resulting intermediate semiconductor structure 221 taken along line Y1-Y1 of FIG. 2N after VBPR pattern processing steps to lithographically pattern a mask and deposit VBPR metal and to fill VBPR trench openings 206, 207 of the structure of FIG. 2M-1. More particularly, a VBPR metal fill material (e.g., Tungsten, Ruthenium, with silicide liner and metal adhesion liner) is deposited to fill VBPR trench opening 206 and then the structure recessed to result in a VBPR structure 216 of a height commensurate with the height of connecting adjacent S/D structures 170A, 170C of GAA NS pFET; in the same process, VBPR metal fill material is deposited in VBPR trench opening 207 and the structure recessed to result in a VBPR structure 217 of a height commensurate with the height of connecting adjacent S/D structures 170B, 170D of GAA NS nFETS being formed. FIG. 2N-2 shows the resulting intermediate semiconductor structure 221 taken along line X1-X1 of FIG. 2N after VBPR metal fill and recess etching. Thus, in the embodiment depicted, a VBPR critical dimension (CD) can be large and also self-aligned and isolated from the nearby FET due to the presence of the S/D spacer which is especially useful for shifted VBPR scheme when N2N and P2P FET spacer is scaling. Depicted in FIG. 2N-2 are replacement metal gate structures 220A, 220B, 220C.

FIG. 2O depicts the top layout view of the resulting intermediate semiconductor structures shown in FIG. 2N including further formed separate VBPR Middle-of-Line (MOL) metal contact structures 226, 227, 228 (VBPR metal contact structures) resulting from patterning and depositing VBPR metal material and CMP surface planarizing according to embodiments of the present disclosure. Referring to FIG. 2O-1, there is illustrated a resulting intermediate semiconductor structure 231 taken along line Y1-Y1 of FIG. 2O after VBPR pattern and metal material deposition processing steps during MOL processing. As shown, the further deposited VBPR metal increases and extends VBPR metal coverage from VBPR structure 216 with further VBPR metal contact structure 226 that overlies and connects adjacent S/D structures 170A, 170C of GAA NS pFET devices being formed and likewise increases and extends VBPR metal coverage from VBPR structure 217 with further VBPR metal contact structure 227 that overlies and wholly connects adjacent S/D structures 170B, 170D of GAA NS nFET devices being formed. FIG. 2O-2 shows the resulting intermediate semiconductor structure 231 taken along line X1-X1 of FIG. 2O after VBPR metal fill and surface CMP planarizing showing extended VBPR metal contact structures 226, 228, where extended VBPR metal contact structure 228 is formed during MOL processing atop the top semiconductor material layer 112 between epitaxially grown S/D structures of replacement metal gate structures 220B, 220C.

FIG. 2P depicts the top layout view of the resulting intermediate semiconductor structures shown in FIG. 2O further indicating resulting cut VBPR metal contact portions 226A, 226B resulting from VBPR cut patterning and dielectric material fill steps for forming a via of dielectric material that results in a “shifted” VBPR metal contact portion 226A according to embodiments of the present disclosure. Referring to FIG. 2P-1, there is illustrated a resulting intermediate semiconductor structure 241 taken along line Y1-Y1 of FIG. 2P after MOL level mask patterning and RIE etching selective to surrounding materials to remove a portion of the overlying VBPR metal contact structure 226 and remove any contiguous via portion of the VBPR structure 216 that electrically connects to one side of the S/D structure 170C. This removed contiguous portion is then filled with insulating dielectric material to form dielectric material via 196. The formed dielectric material via 196 extends to below the BDI dielectric material layer 162 and effectively shifting the VBPR metal contact structure such that the VBPR metal contact structure only contacts a sidewall of one S/D structure 170A. This results in a structure 241 having a bottom VBPR metal contact portion 216A and a shifted VBPR metal contact portion 216B that remains electrically connected to the sidewall of adjacent S/D structure 170A of GAA NS pFET and separates the VBPR MOL metal contact structure 226 into remaining separated and isolated metal contact portions 226A, 226B of the VBPR MOL metal contact structure 226 shown in FIG. 2O-1. This step prevents extended epi S/D structure 170C on the top from shorting to VBPR. As shown in FIG. 2P-1, the shifted VBPR structure includes a bottom VBPR metal contact portion 216A of a first critical dimension (width) and a second VBPR metal contact portion 216B of a second critical dimension (width). FIG. 2P-2 shows the resulting intermediate semiconductor structure 241 taken along line X1-X1 of FIG. 2P after VBPR cut patterning and dielectric material fill steps that result in the formed shifted VBPR metal material structure. The cutting of the VBPR metal contact and formation of dielectric material via 196 ensures that enough shifted VBPR metal remains even when devices are scaled to very small pitches, while preventing any potential of short circuits.

Referring to FIG. 2Q-1, there is illustrated a resulting intermediate semiconductor structure 251 taken along line Y1-Y1 of FIG. 2P after further BEOL processing to form vias, metal lines and contact structures (not shown) atop the structure 241 of FIG. 2P-1 and performing a carrier bonding step to bond an oxide layer of a second carrier wafer 256 to an oxide layer (not shown) at a topmost level of BEOL layer 254 using known processes. This results in an exemplary intermediate semiconductor structure 251 including a formed metal via contact structure 252 electrically connecting the separated VBPR metal contact portion 226B to a further BEOL level contact or metallization structure feature (not shown) in BEOL layer 254. FIG. 2Q-2 shows the resulting intermediate semiconductor structure 251 taken along line X1-X1 of FIG. 2P after forming a further interlevel metal via contact structure 253 electrically connecting the VBPR metal contact structure 228 to a further BEOL level contact or metallization structure feature (not shown) in BEOL layer 254. Bonded to a topmost level of BEOL layer 254 is the second carrier wafer 256.

That is, a wafer flip is performed and a top insulator layer (not shown) is caused to bond, e.g., using the Smart Tec™ process, to an oxide layer of the second carrier wafer 256.

Further steps are directed to forming a backside power rail (BPR) structure. Referring to FIG. 2R-1, there is illustrated a resulting intermediate semiconductor structure 261 taken along line Y1-Y1 of FIG. 2P after performing steps to “flip” the wafer upon which structures 261 are built and remove the bottom substrate portion 103 by performing a dry RIE etch selective to the etch stop layer 104. FIG. 2R-2 shows the resulting semiconductor structure 261 taken along line X1-X1 of FIG. 2P after performing steps to “flip” the wafer upon which structures 261 are built and remove the bottom substrate portion 103 by performing a dry RIE etch selective to the etch stop layer 104.

Referring to FIG. 2S-1, there is illustrated a resulting intermediate semiconductor structure 271 taken along line Y1-Y1 of FIG. 2 after performing further processing steps upon the flipped wafer to remove the etch step layer 104 and then removing the remaining top substrate portion 105 by one or more wet or dry etch processes. In the non-limiting example embodiment depicted in FIG. 2S-1, the removing of the etch stop layer 104 and the top substrate portion 105 includes opening of trenches 272 underneath each respective bottom BDI dielectric material layer 162 of each respective formed adjacent S/D structure 170A, . . . , 170D and particularly, an elongated trench 272 between VBPR metal contact portion 216A and each adjacent STI structure 140 on each side, and an elongated trench 272 between VBPR structure 217 and each adjacent STI structure 140 on each side. Subsequent steps include the depositing of a backside interlevel dielectric material (BILD) material 275 such as an oxide, low-k oxide, nitride to fill each of the trenches 272. A final CMP planarizing step is performed that stops on the STI structure 140 to render a planar bottom surface 276 co-planar with surfaces of VBPR metal contact portion 216A, VBPR structure 217 and each remaining adjacent STI structure 140 surfaces. FIG. 2S-2 shows the resulting semiconductor structure 271 taken along line X1-X1 of FIG. 2 after performing steps to remove the etch step layer 104 and then remove the remaining top substrate portion 105 that opens trenches 272 that are filled with BILD material 275 to isolate the bottom VBPR metal contact portion 216A of the shifted VBPR and isolate the VBPR structure 217 between successive STI structures 140.

FIG. 2T depicts the top layout view of the semiconductor structures shown in FIG. 2P further indicating underlying BPR 15 for providing a signal, e.g., Vdd power signal, to VBPR metal contact portion 216A associated with GAA NS pFETS and underlying BPR 16 for providing a further signal, e.g., Vss power signal, to VBPR structure 217 associated with GAA NS nFETs. Referring to FIG. 2T-1, there is illustrated a resulting intermediate semiconductor structure 281 taken along line Y1-Y1 of FIG. 2T after building, on the “flipped” wafer, a further BILD material layer 285 atop the planar bottom surface 276, lithographically patterning a mask and opening up trenches in alignment with respective VBPR metal contact portions 216A, VBPR structure 217 corresponding to power rail conductors to be built, and then filling the trench openings with metal conductor material such as Cu, Ru, Co, etc., with adhesion metal liners to form underlying BPR 15, e.g., for providing a Vdd power to VBPR metal contact portion 216A and form underlying BPR 16, e.g., for providing a Vss power to the VBPR structure 217. Subsequent steps include the building of a backside power delivery network (BSPDN) 14 for connecting power source providing Vdd power to the underlying BPR 15 and the shifted VBPR metal contact portions 216A, 216B and for connecting power source providing Vss power to the underlying backside power rail 16 and the VBPR structure 217. FIG. 2T-2 shows the resulting semiconductor structure 281 taken along line X1-X1 of FIG. 2T after performing steps to form at least underlying BPR 15 for providing a Vdd power to shifted VBPR metal contact portion 216A and form underlying backside power delivery network 14.

The shifted VBPR structure and method herein avoids risk of shorting to a nearby FET as N2N FET and P2P FET as dimensions scale. That is, the embodiment herein provides a contact to a source/drain through a via to BPR which is shifted-contacting the sidewalls of the S/D of FETs when needed with a dielectric cut (a dielectric cut into a VBPR) to prevent short to the VBPR when contact is not needed. Plus, the maintaining of a full width (CD1) of the bottom portion of shifted VBPR provides a robust VBPR metal volume so as to improve resistance, power delivery, performance and reliability and allows for easier fabrication. Further, it is advantageous to have S/D structure that contacts to a MOL contact with isolation to separate it from shifted VBPR and S/D that contacts to shifted VBPR without spacer to expand VBPR CD.

Further, the presence of an asymmetric spacer around the source/drain further prevents the diamond epi S/D growth. The asymmetric spacer further allows contact to VBPR when needed which makes for easier contact to backside power with more shrinking for advanced technological nodes. That is, the shifted VBPR structure takes less space, allowing more shrinking for more advanced technological nodes and removes the concern of a via VBPR short circuit to a nearby source or drain (S/D) structure of an adjacent FET, as the FET devices scale.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor structure comprising:
a first dielectric material layer having a backside power rail structure;
a second dielectric material layer atop the first dielectric material layer and having a first field effect transistor (FET) device and a second FET device; and
a backside metal contact structure within the second dielectric layer between the first FET device and the second FET device, the backside metal contact structure having a first portion contacting the backside power rail structure and a second via portion electrically contacting only a sidewall of a source or drain structure of the first FET device.

2. The semiconductor structure as claimed in claim 1, wherein the backside metal contact structure comprises an insulating via structure between the first FET device and the second FET device, the insulating via structure contacting only a sidewall of a source or drain structure of the second FET device.

3. The semiconductor structure as claimed in claim 1, wherein the first portion of the backside metal contact structure contacting the backside power rail structure is of a first width and the second via portion of the backside metal contact structure contacting only a sidewall of the source or drain of the first FET device is of a second width, the first width being greater than the second width.

4. The semiconductor structure as claimed in claim 2, wherein the backside metal contact structure further comprises:
a third top portion in contact with the second via portion, the third top portion of the backside metal contact structure in contact with a source or drain structure of the first FET device.

5. The semiconductor structure as claimed in claim 4, further comprising: a separate isolated backside metal contact structure contacting a source or drain structure of the second FET device.

6. The semiconductor structure as claimed in claim 5, further comprising:
a BEOL metallization level atop the second dielectric material layer; and
a conductive via contact structure atop and electrically connecting the separate isolated backside metal contact structure contacting a source or drain of the second FET device to a further metal structure within the BEOL metallization level.

7. The semiconductor structure as claimed in claim 2, further comprising:
an asymmetric source or drain sidewall spacer formed on an opposite side of the source/drain structure of the first FET device that is contacting the second via portion of the backside metal contact structure; and
an asymmetric source or drain sidewall spacer formed on an opposite side of the source/drain structure of the second FET device that is contacting the insulating via structure.

8. The semiconductor structure as claimed in claim 1, further comprising:
a further backside power rail structure in the first dielectric material layer;
a third FET device in the second dielectric material layer and a fourth FET device adjacent the third FET device in the second dielectric material layer; and
a further backside metal contact structure within the second dielectric layer between the third FET device and the fourth FET device, the further backside metal contact structure electrically contacting the further backside power rail structure and electrically contacting both sidewalls of the source or drain structure of the third FET device and the fourth FET device facing each other.

9. The semiconductor structure as claimed in claim 8, wherein each respective first FET device, second FET device, third FET device and fourth FET device is a gate-all-around (GAA) field effect transistor device, each having a vertical stack of spaced apart nanosheet (NS) channels surrounded by a respective gate structure and epitaxially grown source or drain structure contacting one end of the vertical stack of NS channels of the respective FET device.

10. The semiconductor structure as claimed in claim 8, wherein the first FET and second FET devices are of a first FET type and the third FET device and fourth FET device are of a second FET type.

11. A method of forming a semiconductor structure comprising:
forming atop a substrate layer of a first wafer, an interlevel dielectric (ILD) material layer;
forming at the ILD material layer a first field effect transistor (FET) device, and a second FET device;
forming a trench opening between a sidewall of a source or drain structure of the first FET device and a facing sidewall of a source or drain structure of the second FET device, the trench opening exposing a sidewall of the source or drain structure of the first FET device and exposing a facing sidewall of the source or drain structure of the second FET device;
filling the trench opening with a metal contact material to form a backside metal contact structure contacting the exposed sidewalls of the source or drain structures of the first FET device and second FET device;
removing a portion of the backside metal contact structure contacting the sidewall of the source or drain structure of the first FET device; and
filling the removed portion with a dielectric material such that a shifted portion of the backside metal contact structure remains in electrical contact with only the facing sidewall of the source or drain structure of the second FET device.

12. The method as claimed in claim 11, wherein the removing a portion of the backside metal contact structure results in the backside metal contact structure having:
a first bottom contact portion of a first width, and the shifted backside metal contact portion of a second width to contact only a sidewall of the source or drain of the second FET device, the first width being greater than the second width.

13. The method as claimed in claim 11, wherein each the source or drain structure of the first FET device and the source or drain structure of the second FET device comprises a surrounding sidewall dielectric spacer, the method further comprising:
etching to remove a portion of the surrounding sidewall dielectric spacer of the source or drain structure of the first FET device to result in a first remaining asymmetric sidewall spacer and to remove a portion of the surrounding sidewall dielectric spacer of the source or drain structure of the second FET device to result in a second remaining asymmetric sidewall spacer, each the first remaining asymmetric sidewall spacer and second remaining asymmetric sidewall spacer of the source or drain structures being disposed on opposing, non-facing sides of the source or drain structures of the respective first FET device and second FET device.

14. The method as claimed in claim 13, wherein prior to the etching to remove a portion of the surrounding sidewall dielectric spacer to result in the first remaining asymmetric sidewall spacer and to remove a portion of the surrounding sidewall dielectric spacer to result in the second remaining asymmetric sidewall spacer, the method further comprising:
forming a dielectric material layer atop the source or drain structure of the first FET device and atop the source or drain structure of the second FET device, said dielectric material layer further formed in between the source or drain structure of the first FET device and the source or drain structure of the second FET device;
forming a mask layer atop the formed dielectric material layer;
patterning the mask layer to define portions of the dielectric material layer to remain covering the sidewall dielectric spacer to remain surrounding the source or drain structure of the first FET device and to define portions of the sidewall dielectric spacer to remain surrounding the source or drain structure of the second FET device; and
etching, using the patterned mask layer, the dielectric material layer to expose a portion of the surrounding sidewall dielectric spacer to be removed from the source or drain structure of the first FET device and to expose a portion of the surrounding sidewall dielectric spacer to be removed from the source or drain structure of the second FET device.

15. The method as claimed in claim 12, wherein the filling the trench opening with a metal contact material further comprises:
forming a middle-of-line (MOL) top backside metal contact structure electrically contacting a top of the source or drain structure of the first FET device and further contacting a top of the source or drain structure of the second FET device,
wherein the removing a portion of the backside metal contact structure results in isolating a first portion of the top backside metal contact structure in contact with the source or drain structure of the first FET device and isolating a second portion of the top backside metal contact structure in contact with the source or drain structure of the second FET device.

16. The method as claimed in claim 15, further comprising:
flipping the first wafer;
removing the substrate layer and filling in removed portions of the substrate layer with a bottom interlevel dielectric (BILD) material layer; and
forming within the BILD material layer, a backside power rail (BPR) structure in electrical contact with the first bottom contact portion of the backside metal contact structure.

17. The method as claimed in claim 15, further comprising:
forming a further metal structure during a back-end-of-line (BEOL) semiconductor manufacturing process; and
forming a conductive via contact structure atop one of the isolated first portion or isolated second portion of the top backside metal contact structures for electrically contacting the formed further metal structure.

18. A semiconductor structure comprising:
a first dielectric material layer having a first backside power rail structure and a second backside power rail structure;
a second dielectric material layer atop the first dielectric material layer and having a first field effect transistor (FET) device and a second FET device, the first FET device and second FET device of a first conductivity type, the second dielectric material layer having a third FET device and a fourth FET device of a second conductivity type; and
a first backside metal contact structure within the second dielectric layer between the first FET device and the second FET device, the backside metal contact structure having a first portion contacting the first backside power rail structure and a second via portion electrically contacting only a sidewall of a source or drain structure of the first FET device; and
a second backside metal contact structure within the second dielectric layer between the third FET device and the fourth FET device, the second backside metal contact structure having portions contacting the second backside power rail structure and portions wholly contacting sidewalls of both a source or drain structure of each third FET device and fourth FET device.

19. The semiconductor structure as claimed in claim 18, wherein the first backside metal contact structure comprises an insulating via structure between the first FET device and the second FET device, the insulating via structure contacting only a sidewall of the source or drain structure of the second FET device.

20. The semiconductor structure as claimed in claim 18, wherein the first portion of the first backside metal contact structure contacting the backside power rail structure is of a first width and the second via portion of the first backside metal contact structure contacting only a sidewall of the source or drain of the first FET device is of a second width, the first width being greater than the second width.
